(19) United States
(12) Patent Application Publication
(10) Pub. No.: US 2010/0258344 A1
(43) Pub. Date: Oct. 14, 2010

(54) FLAME RETARDANT EMI SHIELDS

(75) Inventor: Larry D. Creasy, JR., St. Clair, MO (US)

Correspondence Address: HARNESS, DICKEY, & PIERCE, P.L.C, 7700 Bonhomme, Suite 400, ST. LOUIS, MO, 63105, US

(73) Assignee: LAIRD TECHNOLOGIES, INC., Chesterfield, MO (US)

(21) Appl. No.: 12/821,947

(22) Filed: Jun. 23, 2010

Related U.S. Application Data
(63) Continuation-in-part of application No. 11/143,333, filed on Jun. 2, 2005.
(60) Provisional application No. 60/651,252, filed on Feb. 9, 2005.

(51) Int. Cl. H05K 9/00; C08L 75/04; C08K 5/3492

(52) U.S. Cl. 174/388; 524/590; 524/101

(57) ABSTRACT

An example electromagnetic interference shield generally includes a resilient core member and an electrically conductive layer. An adhesive bonds the electrically conductive layer to the resilient core member. The adhesive may include halogen-free flame retardant.

### CROSS-REFERENCE TO RELATED APPLICATIONS

This application is a continuation-in-part of U.S. patent application Ser. No. 11/143,333 filed Jun. 2, 2005, which, in turn, claims the benefit of U.S. Provisional Application No. 60/651,252 filed Feb. 9, 2005. The entire disclosures of the applications identified in this paragraph are incorporated herein by reference in their entirety.

### FIELD

The present disclosure generally relates to electromagnetic interference (EMI) shielding, and more particularly (but not exclusively) to flame retardant fabric-over-foam EMI shields formed from environmentally friendly materials, such as halogen-free flame retardants (also termed, fire retardants).

### BACKGROUND

This section provides background information related to the present disclosure which is not necessarily prior art.

The operation of electronic devices generates electromagnetic radiation within the electronic circuitry of the equipment. Such radiation results in electromagnetic interference (EMI) or radio frequency interference (RFI), which can interfere with the operation of other electronic devices within a certain proximity. Without adequate shielding, EMI/RFI interference may cause degradation or complete loss of important signals, thereby rendering the electronic equipment inefficient or inoperable. A common solution to ameliorate the effects of EMI/RFI is through the use of shields capable of absorbing and/or reflecting EMI energy. These shields are typically employed to localize EMI/RFI within its source, and to insulate other devices proximal to the EMI/RFI source.

The term “EMI” as used herein should be considered to generally include and refer to EMI emissions and RFI emissions, and the term “electromagnetic” should be considered to generally include and refer to electromagnetic and radio frequency from external sources and internal sources. Accordingly, the term shielding (as used herein) generally includes and refers to EMI shielding and RFI shielding, for example, to prevent (or at least reduce) ingress and egress of EMI and RFI relative to an enclosure in which electronic equipment is disposed.

### SUMMARY

This section provides a general summary of the disclosure, and is not a comprehensive disclosure of its full scope or all of its features.

Example embodiments of the present disclosure generally relate to EMI shields. Example EMI shields generally include a resilient core member and an electrically conductive layer. An adhesive bonds the electrically conductive layer to the resilient core member. The adhesive includes halogen-free flame retardant.

In one example embodiment, an EMI shield generally includes a resilient core member comprising cellular polymeric foam, an electrically conductive layer, and an adhesive bonding the electrically conductive layer to the resilient core member. In this example embodiment, the electrically conductive layer has a surface resistivity of less than about 0.2 ohms per square after at least about 1,000 hours of exposure of the EMI shield to a temperature of at least about 40 degrees Celsius and a relative humidity of at least about 90%. The adhesive includes about 30% to about 63% by dry weight of halogen-free flame retardant, and has no more than a maximum of 900 parts per million chlorine, no more than a maximum of 900 parts per million bromine, and no more than a maximum of 1,500 parts per million total halogens. And, the EMI shield has a flame rating of V-0 under Underwriter's Laboratories (UL) Standard No. 94.

In another example embodiment, an EMI shield includes a halogen-free fabric-over-foam EMI shielding gasket. Here, the example EMI shielding gasket generally includes a resilient core member comprising urethane foam, an electrically conductive layer, and a thermoplastic polyurethane adhesive bonding the electrically conductive layer to the resilient core member with a bond strength of at least 4 ounces per inch width. The resilient core member is free of flame retardant and has a density between 3.5 pounds per cubic foot and 4.2 pounds per cubic foot and a compression set between 5% and 15%. The electrically conductive layer has a surface resistivity of less than 0.07 ohms per square after at least 1,000 hours of exposure of the EMI shield to a temperature of at least 40 degrees Celsius and a relative humidity of at least 90%. And, the thermoplastic polyurethane adhesive defines a layer having a thickness of 0.5 millimeters or less. The resilient core member, the electrically conductive layer, and the thermoplastic polyurethane adhesive combined have no more than a maximum of 900 parts per million chlorine, no more than a maximum of 900 parts per million bromine, and no more than a maximum of 1,500 parts per million total halogens such that the gasket is halogen free. And, the EMI shield has a flame rating of V-0 under Underwriter's Laboratories (UL) Standard No. 94.

Example embodiments of the present disclosure also generally relate to adhesives suitable for use in EMI shields. In one example embodiment, an adhesive includes a thermoplastic polyurethane adhesive. Here, the thermoplastic polyurethane adhesive generally includes about 30% to about 63% by dry weight of halogen-free flame retardant. The thermoplastic polyurethane adhesive is configured to produce, at a thickness of the thermoplastic polyurethane adhesive of about 0.5 millimeters or less, a bond strength of at least about 4 ounces per inch width to a polyester film, a bond strength of at least about 10 ounces per inch width to a foam material, and a bond strength of at least about 10 ounces per inch width to a fabric material. And, the thermoplastic polyurethane adhesive has no more than a maximum of 900 parts per million chlorine, no more than a maximum of 900 parts per million bromine, and no more than a maximum of 1,500 parts per million total halogens.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1A is a front elevation view of an example embodiment of an EMI shield;

FIG. 1B is a perspective view of the EMI shield of FIG. 1A;

FIG. 1C is a perspective view of another example embodiment of an EMI shield;

FIG. 2 is an example line graph of load versus time showing bond strength of an adhesive that includes about 63% by dry weight of halogen-free flame retardant according to an example embodiment;

FIG. 3 is an example line graph of load versus time showing bond strength of an adhesive that includes about 50% by dry weight of halogen-free flame retardant according to an example embodiment;

FIG. 4 is a table listing example fabrics that can be provided with halogen-free flame retardant according to various example embodiments;

FIG. 5 is a table summarizing data collected during crush and fold testing of a nylon ripstop (NRS) fabric coated with urethane, and a NRS fabric coated with halogen-free flame retardant urethane according to example embodiments;

FIG. 6 is an example line graph created with data from the table shown in FIG. 5 and illustrating surface resistivity (conductivity) versus number of cycles during the crush and fold testing;

FIG. 7 is an example line graph of surface resistivity versus number of cycles during inflated diaphragm abrasion testing of a NRS fabric coated with urethane, and a NRS fabric coated with halogen-free flame retardant urethane according to example embodiments;

FIG. 8 is an example line graph of shielding effectiveness versus frequency for a NRS fabric coated with urethane, and a NRS fabric coated with halogen-free flame retardant urethane according to example embodiments;

FIG. 9 is an example line graph of shielding effectiveness versus frequency for the NRS fabrics shown in FIG. 8 after one week of exposure at 60 degrees Celsius and 90% relative humidity;

FIG. 10 is another example line graph of shielding effectiveness versus frequency for the NRS fabrics shown in FIGS. 8 and 9 after two weeks of exposure at 60 degrees Celsius and 90% relative humidity;

FIG. 11 is another example line graph of shielding effectiveness versus frequency for the NRS fabric coated with halogen-free flame retardant urethane shown in FIGS. 8-10 after eight weeks of exposure at 60 degrees Celsius and 90% relative humidity; and

FIG. 12 is an example line graph of load versus time showing bond strength of an adhesive that includes halogen-free flame retardant according to one example embodiment of the present disclosure.

### DETAILED DESCRIPTION

Example embodiments will now be described more fully with reference to the accompanying drawings.

According to various aspects, there are disclosed herein example embodiments of electromagnetic interference (EMI) shields, such as, for example, fabric-over-foam (FOF) EMI shielding gaskets, input/output gaskets, profile gaskets, other shielding devices, etc. The EMI shields may be used in a wide range of applications, installations, and electronic equipment such as, for example, computer servers, desktop computers, digital cameras, internal and external hard drives, liquid crystal displays, medical equipment, notebook computers, plasma display panels, printers, set top boxes, telecommunications enclosure cabinets, other electronic devices, other related devices, etc.

Example embodiments of the EMI shields are able to achieve desired flame ratings under the Underwriters Laboratories Standard No. 94, “Tests for Flammability of Plastic Materials for Parts in Devices and Appliances” (5^{th} Edition, Oct. 29, 1996) (hereinafter, UL-94). For example, some EMI shields are able to achieve higher flame ratings of V-0. Other EMI shields are only able to achieve lower flame ratings, such as V-1, V-2, HB, or HF-1. Example embodiments of the EMI shields may be able to achieve these desired flame ratings to minimum thicknesses of the EMI shields of at least about 1 millimeter. The desired UL-94 flame rating of the example embodiments of the EMI shields can depend, for example, on the particular application or installation for an EMI shield.

Flame ratings can be determined using UL-94 or using an American Society for Testing and Materials (ASTM) flammability test. UL-94 includes flame ratings of V-0, V-1, V-2, HB, and HF-1, where V-0 is a higher flame rating and HF-1 is a lower flame rating. Notably, the V-0 rating is much more difficult to achieve than the V-1, V-2, HB, and HF-1 ratings. A sample product achieving a lower V-1 rating would not necessarily achieve a higher V-0 rating. Indeed, V-0 and V-1 ratings of sample products are treated as being mutually exclusive for the sample products and are not overlapping. In other words, a sample product identified as having a V-1 rating would not also be considered as having a V-0 rating (otherwise it would be identified as having a V-0 rating).

Under UL-94, flame ratings are determined for a sample product based on burn tests for sets of five specimens of the sample product. Table 1 indicates criteria used for determining UL-94 V-0, V-1, V-2 flame ratings. For example, to achieve a flame rating of V-0, afterflame time (t₁ or t₂) for each individual specimen of the sample product tested must be less than or equal to 10 seconds, total afterflame time (t₁ plus t₂ for all five specimens) must be less than or equal to 50 seconds, and afterflame plus afterglow time (t₂ plus t₃) for each individual specimen must be less than or equal to 30 seconds. At the least, each of these criteria must be satisfied to achieve a flame rating of V-0. As can be appreciated, the V-0 rating is much more difficult to achieve than the V-1 or V-2 ratings.

TABLE 1

| UL-94 CRITERIA CONDITIONS | V-0 | V-1 | V-2 |
|---|---|---|---|
| Afterflame time for each individual | ≦10 s | ≦30 s | ≦30 s |
| specimen t₁ or t₂ | | | |
| Total afterflame time for any | ≦50 s | ≦250 s | ≦250 s |
| condition set (t₁ plus t₂ for the | | | |
| five specimens) | | | |
| Afterflame plus afterglow time for | ≦30 s | ≦60 s | ≦60 s |
| each individual specimen after the | | | |
| second flame application (t₂ plus t₃) | | | |
| Afterflame or afterglow of any | No | No | No |
| specimen up to the holding clamp | | | |
| Cotton indicator ignited by | No | No | Yes |
| flaming particles or drops | | | |

Example embodiments of the EMI shields may be environmentally friendly and may be viewed as halogen-free per International Electrotechnical Commission (IEC) International Standard IEC 61249-2-21 (page 15, November 2003, First Edition). International Standard IEC 61249-2-21 defines “halogen free” (or free of halogen) for Electrical and Electronic Equipment Covered Under the European Union's Restriction of Hazardous Substances (RoHS) directive as having no more than a maximum of 900 parts per million chlorine, no more than a maximum of 900 parts per million bromine, and no more than a maximum of 1,500 parts per million total halogens. The phrases “halogen free,” “free of halogen,” and the like are similarly used herein. Example embodiments of the EMI shields may thus have flame ratings of V-0 under UL-94, may be halogen free as defined by the IEC 61249-2-21 standard, and may also provide RoHS compliant EMI shielding technology.

Example embodiments of EMI shields generally include a resilient core member and an electrically conductive layer. An adhesive (e.g., an adhesive layer, etc.) bonds the electrically conductive layer to the resilient core member. In some example embodiments of the EMI shields, the resilient core member, the electrically conductive layer, and the adhesive may each be halogen free. In other example embodiments of the EMI shields, the resilient core member, the electrically conductive layer, and the adhesive combined may be halogen free (such that the example EMI shields are halogen free).

Example embodiments of EMI shields may include a resilient core member comprising a foam material (e.g., a cellular polymeric foam such as an open celled foam, a closed cell foam, a urethane foam (e.g., a polyester foam, a polyether foam, etc.), etc.). Other materials may be used for the resilient core member, such as those disclosed hereinafter.

In some example embodiments, the resilient core member may comprise a foam material having a compression set (per ASTM D3574 (test D)) of less than about 15% and/or a density of between about 3 pounds per cubic foot and about 5 pounds per cubic foot (e.g., between about 3.5 pounds per cubic foot and about 4.2 pounds per cubic foot, etc.).

In some example embodiments, the resilient core member may not include (and may be free of) any flame retardant (and may not have any added thereto at any time), for example, either during the process of making the resilient core member or in the final product of the resilient core member used in the example EMI shields. For example, the resilient core member may not be flame rated, the resilient core member may include less than about 1,000 parts per million of flame retardant, the resilient core member may include undetectable amounts of flame retardant, the resilient core member may include a de minimis or trivial amount of flame retardant; etc. In other example embodiments, the resilient core member may be entirely free of flame retardants.

In some example embodiments, the resilient core member (e.g., a foam material of the resilient core member, etc.) may not include (and may be free of, and may not have added thereto at any time) any ammonium compounds (e.g., ammonium carbonate, etc.), chlorine, bromine, antimony, compounds thereof, etc. either during the process of making the resilient core member or in the final product of the resilient core member used in the example EMI shields. And, such example embodiments of the EMI shields may be able to achieve flame ratings of V-0 under UL-94 (without having any flame retardant added to or present in the resilient core member at any time). This is a significant accomplishment given that presence of flame retardant inside a core member (and particularly inside a foam core member) can tend to decrease the core member's performance in compression set and compression load deflection tests.

In some example embodiments, the resilient core member may be provided (e.g., applied, coated, impregnated, mixed, plated, vapor deposited, fabricated, formed, combinations thereof, etc.) with flame retardants (e.g., halogen-free flame retardants, etc.). For example, various embodiments may include a resilient core member provided with halogen free flame retardant such that the resilient core member is able to achieve a flame rating under UL-94 of HF-1.

In some example embodiments, the resilient core member may have a density of at least about 3 pounds per cubic foot or more (e.g., about 3 pounds per cubic foot, about 3.1 pounds per cubic foot, about 3.5 pounds per cubic foot, about 4 pounds per cubic foot, about 5 pounds per cubic foot, etc.). For example, the inventor hereof has recognized that using a foam product for the resilient core member having a density of at least about 3.5 pounds per cubic foot provides a better compression set that is acceptable for use, for example, with FOF EMI gaskets, etc. as compared to less dense foam materials (e.g., foam materials having densities of about 3 pounds per cubic foot or less, etc.). But it is noted that in example embodiments where the resilient core member is made from urethane foam, flammability of the resilient core member may increase as the density of the resilient core member increases (e.g., a resilient core member having a density of about 4 pounds per cubic foot may be more flammable than a resilient core member having a density of about 3 pounds per cubic foot, etc.). Thus, it may become more difficult to achieve higher flame ratings (e.g., flame ratings of V-0 under UL-94, etc.) for EMI shields when using these higher density urethane foam resilient core members (e.g., a urethane foam resilient core member having a density of about 4 pounds per cubic foot or more, etc.). But as explained herein, this is exactly what the inventor has accomplished in various example embodiments. Other foam products may be used within the scope of the present disclosure.

Example embodiments of the EMI shields may include an electrically conductive layer. In some example embodiments, the electrically conductive layer may comprise a metal coated textile material (e.g., a fabric, etc.) such as, for example, a nylon ripstop (NRS) material, a polyester material, a cotton material, a combination thereof, etc. that is coated (e.g., plated, etc.) with nickel, copper, a combination thereof, etc. Thus, in some of these example embodiments, the electrically conductive layer may include a plated conductive fabric. Other materials may be used for the electrically conductive layer, such as, for example, metallic foils (e.g., aluminum foil, etc.), metal coated plastic films (e.g., aluminum foil and polyester films, aluminum foil and polyethylene terephthalate laminates, etc.), other materials disclosed hereinafter, etc.

In some example embodiments, the electrically conductive layer may have a conductivity (or surface resistivity) of less than about 0.20 ohms per square after at least about 1,000 hours of exposure of the EMI shields made from the electrically conductive layer to a substantially constant temperature of at least about 40 degrees Celsius and a substantially constant relative humidity of at least about 90%. In other example embodiments, the electrically conductive layer may have a conductivity of less than about 0.07 ohms per square (e.g., about 0.04 ohms per square, about 0.03 ohms per square, etc.) under similar conditions.

In some example embodiments, the electrically conductive layer may be provided (e.g., applied, coated, impregnated, mixed, plated, vapor deposited, fabricated, formed, combinations thereof, etc.) with halogen-free flame retardant.

In some example embodiments, the electrically conductive layer may not include any flame retardant (e.g., the electrically conductive layer may not include any halogen-free flame retardant provided thereto, any other flame retardant particles provided thereto, etc.). As such, in these example embodiments the electrically conductive layer may be free of flame retardant. In some of these example embodiments, other materials not containing flame retardant may be added to the electrically conductive layer as desired (in which case the electrically conductive layer is still free of flame retardant). In some of these example embodiments, the electrically conductive layer is also halogen-free.

In some example embodiments, the electrically conductive layer may include a halogen-free flame retardant urethane. The halogen-free flame retardant urethane may be formed, for example, by combining via a substantially continuously, vigorously mixing operation about 35% by weight of Soluol 1024 water-based urethane dispersion (having about 37% solids), about 50% by weight of de-ionized water, and about 15% by weight of phosphorous-based flame retardant. The resulting flame retardant urethane includes about 29% solids and has a viscosity of about 20 centipoise. Accordingly, and after drying in this particular embodiment, the halogen-free flame retardant urethane provided to the electrically conductive portion includes about 46% by dry weight of urethane and about 54% by dry weight of flame retardant. In another embodiment, however, the electrically conductive portion is provided with a halogen-free flame retardant urethane that includes about 52% by dry weight of halogen-free flame retardant and about of about 48% by dry weight of urethane.

In some example embodiments, the electrically conductive layer may include a halogen-free flame retardant urethane coating (e.g., provided to the electrically conductive layer, etc.) with a thickness of about one micron or less. In such example embodiments, the thickness of the halogen-free flame retardant urethane coating can vary across the surface of the fabric. Alternatively, the thickness of the halogen-free flame retardant urethane coating can be substantially uniform across the surface of the fabric. To help maintain electrical conductivity, the electrically conductive fabric may not be entirely permeated or encapsulated with flame retardant urethane.

In some example embodiments, the electrically conductive layer may include a halogen-free corrosion inhibitor (e.g., benzotriazole, or other suitable corrosion inhibitor, for example, selected from the azole family and/or pyrole family, etc.). Depending on the particular corrosion inhibitor used, the corrosion inhibitor may function as a halogen-free flame retardant. In such example embodiments, the corrosion inhibitor may thus be referred to herein as a halogen-free flame retardant. In yet other example embodiments, the electrically conductive fabric may be provided with both a corrosion inhibitor and flame retardant.

In some example embodiments, the electrically conductive layer may include only a fabric material and a conductive metal provided to the fabric material. In other example embodiments, the electrically conductive layer may only include a fabric material, a conductive metal provided to the fabric material, and a halogen-free flame retardant urethane provided to the conductive metal.

Example embodiments of the EMI shields may include an adhesive (e.g., defining an adhesive layer, etc.) comprising a thermoplastic polyurethane resin. In some of these example embodiments, the adhesive may comprise about 25% to about 60% by dry weight (e.g., about 30% by dry weight, about 50% by dry weight, about 55% by dry weight, etc.) of the thermoplastic polyurethane resin (e.g., with flame retardant making up the rest of the adhesive, etc.).

In some example embodiments, the adhesive may be loaded (e.g., fabricated, formed, mixed, etc.) with an effective amount of halogen-free flame retardant (e.g., more than about 30% by dry weight, about 30% to about 70%, about 40% to about 67% by dry weight, about 54.5% to about 63% by dry weight, about 45% to about 56% by dry weight, about 50% by dry weight, about 55% by dry weight, etc.), which may enable the EMI shields to achieve a predetermined flame retardant rating (e.g., a UL-94 flame rating of V-0, etc.). In some of these example embodiments, the EMI shields may include an adhesive loaded with an effective amount of halogen-free flame retardant in combination with halogen-free flame retardant provided to a resilient core member and/or an electrically conductive layer, thereby allowing the EMI shields to achieve a predetermined flame retardant rating (e.g., a UL-94 flame rating of V-0, etc.) while still being halogen free. In other ones of these example embodiments, the EMI shields may include an adhesive loaded with an effective amount of halogen-free flame retardant such that the EMI shields can achieve a predetermined flame retardant rating (e.g., a UL 94 flame rating of V-0, etc.) without flame retardant being provided to the resilient core member and/or the electrically conductive layer.

In some example embodiments, the effective amount of halogen-free flame retardant in the adhesive is less than a predetermined percentage below which the loaded adhesive provides at least a predetermined bond strength (e.g., at least about 10 ounces per inch width as determined, for example, by a 90 degree peel (or T-peel) test at 12 inches per minute, etc.). Thus, it should be appreciated that if too little flame retardant is included in the adhesive, flame resistance will be insufficient. And, if too much flame retardant is included in the adhesive, bond strength will be insufficient. As described herein, the inventor hereof has determined a balance between flame resistance and bond strength. In addition to the amount of flame retardant in the adhesive, the bond strength of the adhesive may also depend on the particular substrate to which it is bonding. By way of example, the bond strength of adhesive having about 56% flame retardant by dry weight may be about 22 ounces per inch width on nickel/copper plated NRS fabric. Also by way of example, the bond strength of adhesive having about 46% flame retardant by dry weight may be about 33 ounces per inch width on nickel/copper plated NRS fabric. The numerical bond strengths disclosed herein were determined by performing a 90 degree peel test at 12 inches per minute.

In some example embodiments, the adhesive may include a thermoplastic polyurethane composite resin composition loaded with halogen-free flame retardant instead of halogen-based flame retardant (such that the adhesive does not include halogenated flame retardants), instead of expandable carbon graphite (ECG) flame retardants, and/or instead of red phosphorous flame retardants (e.g., which can be detected using a microscope, etc.). For example, the adhesive may include halogen-free phosphorous-based flame retardants that do not include ECG or red phosphorus flame retardants. As such, in these example embodiments the adhesive may be viewed as being free of (and not including) halogen (and halogen-based flame retardants), ECG, and/or red phosphorus. EMI shields including such an adhesive may advantageously be capable of achieving UL-94 flame ratings of V-0, and may be able to avoid undesirable effects often associated with red phosphorous flame retardants and/or with ECG flame retardants. Notably when used in an adhesive in an EMI shield, red phosphorus may cause corrosion in the EMI shield and ECG, which is an electrically conductive material, may cause undesirable electrical shorts inside electronic devices.

In some example embodiments, the adhesive (the adhesive layer defined thereby) may have a thickness (e.g., an average thickness, a generally uniform thickness, etc.) of less than about 1 millimeter (e.g., about 0.5 millimeters or less, etc.). In some of these example embodiments, the adhesive layer may have a thickness of about 0.1 millimeters or less (e.g., about 0.09 millimeters, about 0.06 millimeters, etc.).

In some example embodiments, the adhesive may define a single layer of material. For example, in these example embodiments the adhesive may include halogen-free flame retardant mixed therein such that the adhesive and the halogen-free flame retardant together define a single layer of material. EMI shields including this example adhesive may be able to achieve flame ratings of V-0 under UL-94 (e.g., without having any flame retardant added to or present in the resilient core member and/or the electrically conductive layer at any time, etc.). By providing the halogen-free flame retardant to the adhesive in such a manner (so that the adhesive and halogen-free flame retardant define a single layer of material), multiple different layers of material (e.g., a first layer of adhesive and a second, separate layer of flame retardant covering the adhesive, etc.) are not required, for example, to achieve a desired flame rating (e.g., a flame rating of V-0 under UL-94, etc.). As such, the adhesive and halogen-free flame retardant defining a single layer of material may provide cost savings when used to make EMI shields, improved ease in making EMI shields, etc. Previously in the art, such multiple different layers of material were used to achieve desired flame ratings in EMI shields while avoiding problems associated with losing adhesive strength when the flame retardant was mixed into the adhesive.

In some example embodiments, the adhesive may include a solvent-based adhesive. For example, the adhesive may include a thermoplastic polyurethane resin composition (having flame retardant particles mixed therein) made via a wet coating process, where the adhesive is coated onto release paper. Here, a solvent (e.g., toluene, ethyl acetate, water, etc.) may be used to keep the adhesive liquid for coating prior to drying. But after the adhesive dries in a thin film form (e.g., in a layer between a resilient core member and an electrically conductive layer, where the adhesive layer may have a thickness of about 1 millimeter or less (e.g., about 0.09 millimeters, about 0.06 millimeters, etc.), etc.), the solvent evaporates leaving behind the thermoplastic polyurethane resin composition with the flame retardant particles mixed in. The amount of solvent remaining in the adhesive that didn't evaporate is very small (e.g., less than about 0.1%, etc.). The inventor hereof has recognized that using this solvent based wet coating process may lead to better/higher adhesive bond strengths and also may allow for production of very thin adhesive layers (e.g., layers having thicknesses of about 1 millimeter or less (e.g., about 0.09 millimeters, about 0.06 millimeters, etc.), etc.) with enough halogen-free free flame retardant therein to allow EMI shields (e.g., FOF EMI shielding gaskets, etc.) to achieve UL-94 flame ratings of V-0, even when that EMI shields do not include flame retardant additives in the foam and/or do not include ECG flame retardants, halogenated flame retardants, or red phosphorous flame retardants. It is noted that while the solvent may include water (e.g., such that the adhesive may include a water-based adhesive, etc.), solvents such as toluene, ethyl acetate, etc. may allow for more efficient manufacturing of the EMI shields, as water tends to take longer to evaporate during manufacture than do other solvents such as toluene, ethyl acetate, etc.

In some example embodiments, the adhesive may be prepared using suitable devices capable, for example, of effectively dispersing the flame retardant particles within the adhesive at a temperature greater than a melting point of the adhesive to thereby prepare the mixture of the adhesive and the flame retardant particles.

In some example embodiments, the adhesive may include a thermoplastic polyurethane resin composition made via an extrusion process without solvent and requiring no release paper.

In some example embodiments, the adhesive may also include at least one or more additives such as antioxidants, stabilizers, lubricants, reinforcing agents, pigments, colorants, plasticizers, etc. The additives may be included in the adhesive layers in desired amounts (or ranges of amounts) so as to not reduce bond strength and/or flame resistance of the adhesive layers.

In some example embodiments, two or more different kinds of adhesives may be used to define an adhesive layer of an EMI shield.

Any suitable flame retardants may be used in connection with EMI shields of the present disclosure. Example flame retardants may include phosphorous-based flame retardants (e.g., organic phosphorus compounds, phosphinates (e.g., Exolit OP, etc.), diphosphinates, polymers thereof, cyclic phosphonate ester blends, combinations thereof, etc.), nitrogen compounds, ammonium compounds, mineral oxides (e.g., magnesium hydroxide, etc.), metal hydrates (e.g., aluminum trihydrate, etc.), boron compounds (e.g., boric acid, borax, etc.), melainine derivatives (e.g., melamines, melamine cyanurate, melamine phosphate, melamine polyphosphate, melamine borate, etc.), neoprenes, silicones, combinations thereof, etc.

Phosphorus flame retardants may interrupt decomposition in a condensed phase and may increase char yield during combustion, while providing flame retardancy, for example, to the EMI shields. For example, when phosphorus flame retardants are added to the adhesive used in EMI shields, the adhesive may provide flame retardancy to the EMI shields (particularly in EMI shields where the adhesive comprises a resin with high oxygen content, such as thermoplastic polyurethane resin). Here, the char generally includes a layer of carbonized resin caused by combustion. The formation of char helps inhibit spreading of fire through the EMI shields.

Example embodiments of the EMI shields may include combinations of flame retardants, additives, corrosion inhibitors, other compounds, etc. Such combinations may provide improved flame retardancy (e.g., may provide an expandable char layer through a synergy effect of the different flame retardants to thereby inhibiting the spread of oxygen and heat, etc.).

In some example embodiments, the EMI shields may include an adhesive comprising phosphorous flame retardants in combination with melamine derivatives and nitrogen compounds. Here, use of the phosphorous flame retardants in combination with the nitrogen compounds can promote generation of phosphoric acid amide through combustion, which forms an expandable char layer with increased thickness (thereby inhibiting transfer of heat and oxygen required for combustion).

Example embodiments of the EMI shields may include adhesives comprising flame retardants (e.g., halogen-free flame retardants, etc.) having desired particle sizes. Particle sizes of flame retardants may influence physical properties of the adhesive layers. For example, flame retardants with smaller particle sizes may provide improved physical properties and flame retardancy to the adhesive layers (e.g., larger particle sizes may inhibit dispersion within the adhesive layers, etc.). In some of these example embodiments, the flame retardants having particle sizes between about 1 micrometer and about 60 micrometers (and more preferably between about 1 micrometer and about 20 micrometers).

Example embodiments of the EMI shields may include a resilient foam core member and a layer of electrically conductive material bonded to the resilient foam core member with adhesive, where only the adhesive includes flame retardant (e.g., about 40% to about 60% by dry weight of halogen-free flame retardant, etc.). In such example embodiments, the EMI shields are able to achieve flame ratings of V-0 under UL-94 without having flame retardant additives in the resilient foam core member and/or without having flame retardant additives in the electrically conductive layer. As previously described, this is a significant accomplishment given that presence of flame retardant (e.g., flame retardant additives, etc.) inside a foam core can tend to decrease the foam's performance in compression set and compression load deflection tests.

Example embodiments of the EMI shields may generally include a resilient core member, an electrically conductive layer, and an adhesive bonding the electrically conductive layer to the core member. The adhesive may include between about 25% and about 60% by dry weight (e.g., about 55% by dry weight, etc.) of a resin (e.g., a thermoplastic polyurethane resin, etc.), between about 30% and about 50% by dry weight (e.g., about 40% by dry weight, etc.) of an organic phosphorus flame retardant, and between about 1% and about 10% by dry weight (e.g., about 5% by dry weight, etc.) of a melamine derivative flame retardant. The adhesive may also include between about 10% and about 30% by dry weight of an epoxy resin. In addition, the adhesive may have a solids content of between about 25% and about 53%.

Example embodiments of the EMI shields may generally include a resilient core member, an electrically conductive layer, and an adhesive (which includes halogen-free flame retardant) bonding the electrically conductive layer to the core member. The effective amount of halogen-free flame retardant in the adhesive, however, is less than a predetermined percentage below which the adhesive provides at least a predetermined bond strength (e.g., at least about 4 ounces per inch width as determined, for example, by a 90 degree peel test at twelve inches per minute, etc.). In some of these example embodiments, the resilient core member may include foam, and the adhesive bonding the electrically conductive layer to the foam may be capable of providing a bond strength to the foam of at least about 10 ounces per inch width (e.g., about 30 ounces per inch width, etc.). In other ones of these example embodiments, the electrically conductive layer may include fabric, and the adhesive bonding the fabric to the resilient core member may be capable of providing a bond strength to the fabric of at least about 10 ounces per inch width (e.g., about 20 ounces per inch width, etc.). In still other ones of these example embodiments, the electrically conductive layer may include a polyester film, and the adhesive bonding the polyester film to the resilient core member may be capable of providing a bond strength to the polyester film of at least about 4 ounces per inch width.

Example embodiments of the EMI shields may generally include a resilient core member, an electrically conductive layer, and an adhesive which includes halogen-free flame retardant bonding the electrically conductive layer to the core member. In these particular embodiments, the electrically conductive layer may be provided with a halogen-free corrosion inhibitor (e.g., benzotriazole, or other suitable corrosion inhibitor, for example, from the azole family and/or pyrole family, etc.). The corrosion inhibitor can also function as a flame retardant, which in combination with the flame retardant properties of the adhesive enables the shield to achieve a predetermined flame retardant rating (e.g., a UL-94 flame rating of V-0, etc.). The effective amount of halogen-free flame retardant in the adhesive, however, is less than a predetermined percentage below which the loaded adhesive provides at least a predetermined bond strength (e.g., at least about 4 ounces per inch width as determined, for example, by a 90 degree peel test at twelve inches per minute, etc.). Accordingly, these particular embodiments of EMI shields are halogen-free and environmentally friendly.

Example embodiments of the EMI shields may include a core member, an electrically conductive portion, and an adhesive bonding the electrically conductive portion to the core member, wherein the core member, the electrically conductive portion, and the adhesive are each provided with a flame retardant. In these embodiments, the flame retardant applied to the electrically conductive portion can be a corrosion inhibitor, such as benzotriazole or other suitable corrosion inhibitor, for example, selected from the azole family and/or pyrole family, etc.

Example embodiments of the EMI shields may generally include a resilient core member and an electrically conductive layer. In these particular embodiments, the electrically conductive layer is bonded to the core member with an adhesive layer having a thickness of about 0.0025 inches. The inventor hereof has recognized that these EMI shields can achieve a UL-94 flame rating of V-0 without any flame retardant being provided to the electrically conductive layer and/or to the resilient core member. For example, the electrically conductive layer in one of these example embodiments may include a non-flame retardant (Non-FR) urethane coating having about 18% urethane solids such that the weight pick-up from the Non-FR urethane coating was about 0.15 ounces per square yard (opsy). Yet other ones of these example embodiments may include an electrically conductive layer provided with Non-FR urethane having about 10% to about 18% urethane solids such that the weight pick-up on the fabric is between about 0.05 opsy and about 0.35 opsy (e.g., about 0.05 opsy, about 0.15 opsy, about 0.35 opsy, etc.).

Example embodiments of the EMI shields may generally include a resilient core member and an electrically conductive layer. An adhesive, which includes halogen-free flame retardant, bonds the electrically conductive layer to the core member. In these particular embodiments, the electrically conductive layer is provided with a halogen-free corrosion inhibitor (e.g., benzotriazole, or other suitable corrosion inhibitor, for example, selected from the azole family and/or pyrole family, etc.). Depending on the particular corrosion inhibitor used, the corrosion inhibitor may function as a halogen-free flame retardant, in which case, the corrosion inhibitor may thus be referred to herein as a halogen-free flame retardant. This corrosion inhibitor can be added to a urethane coating, which is applied to the electrically conductive layer. The inventor hereof has recognized that when halogen-free EMI shields are exposed to high temperature and relative humidity (e.g., 60 degrees Celsius or higher temperatures, 90% relative humidity or higher) for several days, a small amount of corrosion may form when the EMI shields are in contact with certain metals. Adding a corrosion inhibitor to the EMI shield can greatly improve the corrosion resistance of the halogen-free EMI shield in a high temperature and high humidity environment. In various ones of these example embodiments, the electrically conductive layer of the EMI shield is provided with urethane that includes a corrosion inhibitor additive to thereby help protect the EMI shield from corrosion in high temperature and relative humidity applications. In one example embodiment of a halogen-free EMI shield, the electrically conductive layer is provided with liquid urethane having an amount of Benzotriazole corrosion inhibitor of at least about 2% by liquid weight. In another example embodiment of a halogen-free EMI shield, the electrically conductive layer is provided with liquid urethane having an amount of Benzotriazole corrosion inhibitor of at least about 1% by liquid weight. In a further example embodiment of a halogen-free EMI shield, the electrically conductive layer is provided or coated with a dry urethane film having an amount of Benzotriazole corrosion inhibitor of at least about 4% by dry weight. Alternatively, other suitable corrosion inhibitors and/or in other amounts can be used depending on the particular application in which the EMI shield will be used.

Example embodiments of the EMI shields may generally include a resilient core member, an electrically conductive layer, and an adhesive (which may include halogen-free flame retardant), bonding the electrically conductive layer to the core member. In these example embodiments, the resilient core member, the electrically conductive layer, and/or the adhesive may be free of antimony (e.g., free of antimony-based flame retardants, etc.). In these example embodiments, the resilient core member, the electrically conductive layer, and/or the adhesive may include no more than a maximum of about 1,000 parts per million of antimony (e.g., no more than a maximum of about 2 parts per million of antimony, etc.) (and may thus be considered antimony free (or free of antimony)).

Example embodiments of the EMI shields may include fabric-over-foam (FOF) EMI shielding gaskets that are formed using environmentally friendly flame retardants (e.g., halogen-free flame retardants, etc.) and still are able achieve flame ratings of V-0 under UL-94 while also having adhesive bond strengths of at least about 4 ounces per inch width (e.g., as determined by standard testing, for example, such as a 90 degree peel at 12 inches per minute, etc.) to a foam and a scrim attached to the foam and retaining properties suitable (e.g., shielding effectiveness, bulk resistivity, etc.) for EMI shielding applications.

Example embodiments of the EMI shields may consist of only three layers, including a resilient core member, an adhesive (e.g., with halogen-free flame retardant added thereto, etc.), and an electrically conductive layer. In these example embodiments, the resilient core member is (or constitutes) a first, inner layer. The adhesive is (or constitutes) a second, middle layer. And, the electrically-conductive layer is (or constitutes) a third, outer layer. Comparatively, the middle layer (the adhesive) may be relatively thin and have a thickness, for example, of about 0.09 millimeters, etc. In these example EMI shield three-layer construction embodiments, the adhesive and any halogen-free flame retardant mixed therein is included in a single layer (the second, middle layer). The inventor has recognized that having such a three-layer construction may provide a technical effect of achieving an acceptable flame rating (e.g., a UL-94 flame rating of V-0, etc.) while using fewer layers (which may improve manufacturability) as compared to using two separate, distinct layers for the adhesive (as one separate layer) and the flame retardant (as another separate layer). In the inventor's example EMI shield three-layer construction embodiments, the adhesive bonds the electrically conductive layer to the resilient core member with a sufficient bond strength (e.g., at least about 4 ounces per inch width, etc.) and includes an amount of halogen-free flame retardant mixed therein such that the shield preferably has a UL-94 flame rating of V-0.

Example embodiments of the EMI shields may be configured to have (but are not required to have) at least one or more of a shielding effectiveness of greater than about 60 decibels (per Military Standard MIL-STD 285 (mod)) (e.g., about 90 decibels, about 100 decibels, etc.); a compression set of between about 5% and about 25% (per ASTM D3574 (test D)); low compression of closure forces from about 5 to about 10 pounds per foot; low surface resistivities (conductivities) (e.g., about 0.07 ohms/square or less, etc. (per ASTM F390)); service temperatures ranging from about −40 degrees Fahrenheit to about 158 degrees Fahrenheit (−40 degrees Celsius to about 70 degrees Celsius); and/or relatively high abrasion resistances.

As described, the inventor hereof has developed example embodiments of unique halogen-free flame retardant adhesives which may be used in any of the various example EMI shields disclosed herein to bond the electrically conductive layer to the resilient core member. For example, a halogen-free flame retardant adhesive disclosed herein and developed by the inventor may be used to bond a metal-coated fabric (e.g., nickel/copper coated textile, etc.) to a urethane (polyester) foam to thereby provide an EMI fabric-over-foam gasket where the gasket is able to achieve a flame rating of V-0 under UL-94 even when the gasket is halogen-free (as defined by IEC 61249-2-21), does not contain flame retardants in the foam, and does not include expandable carbon graphite flame retardants, halogenated flame retardants, or red phosphorous flame retardants.

The inventor hereof has also disclosed example embodiments of EMI shields that are able to achieve flame ratings of V-0 under UL-94 without having flame retardant additives in the resilient core member and without using either expandable carbon graphite flame retardants or halogenated flame retardants. At least some example embodiments do not include red phosphorous flame retardants.

Other aspects of the present disclosure include methods of making and using EMI shields. Additional aspects of the present disclosure include electrically conductive materials, such as metal coated (e.g., nickel/copper coated, etc.) textiles, etc., that are provided with (e.g., coated, impregnated, combinations thereof, etc.) halogen-free flame retardants and/or corrosion inhibitors. Further aspects include EMI shields in which the electrically conductive layer is not provided with flame retardant or a corrosion inhibitor.

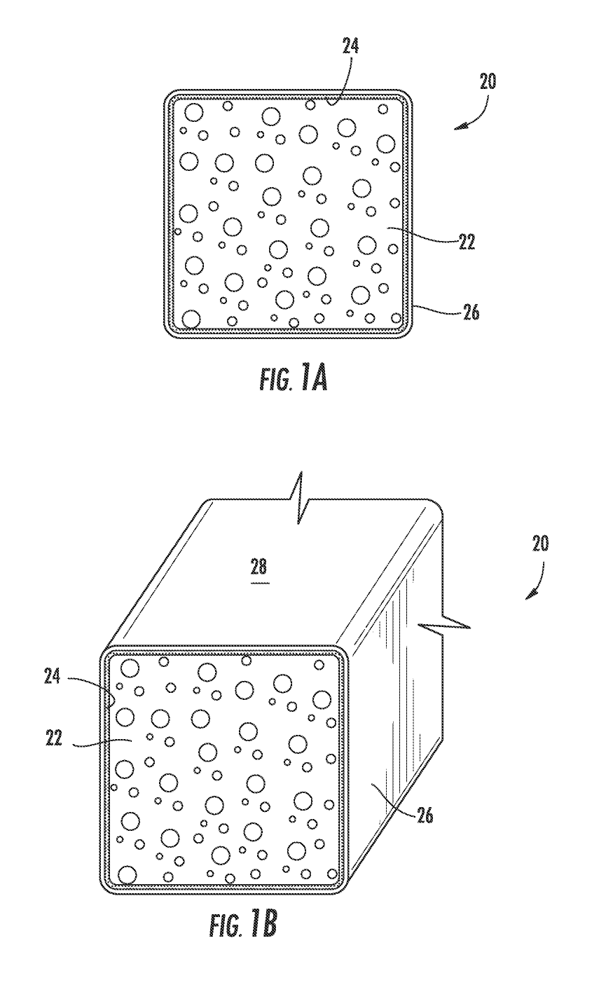

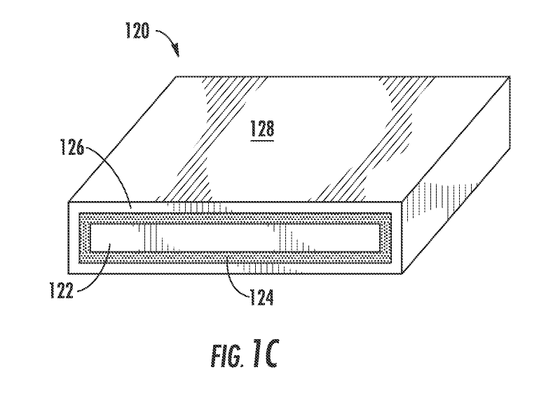

With reference now to the drawings, FIGS. 1A and 1B illustrate an example embodiment of an EMI shield 20 embodying one or more aspects of the present disclosure. As shown, the shield 20 includes a resilient core member 22, an electrically conductive layer 26 generally surrounding the resilient core member 22, and an adhesive layer 24 bonding the electrically conductive layer 26 to the resilient core member 22. The adhesive layer 24 may include an effective amount of flame retardant such that the EMI shield 20 has a UL-94 flame rating of V-0. In other example embodiments, adhesive layers may include less flame retardant (or lesser effective flame retardants) such that EMI shields can only achieve lower UL-94 flame ratings such as V-1, V-2, HB, or HF-1.

The electrically conductive layer 26 of the illustrated EMI shield 20 may or may not be provided with halogen-free flame retardant and/or a halogen-free corrosion inhibitor (which may also function as and thus be referred to herein as a flame retardant). In this particular illustrated embodiment, the electrically conductive layer 26 is provided a coating 28 which includes both urethane and halogen-free flame retardant. In addition to, or as an alternative to, the flame retardant, the coating 28 can include a corrosion inhibitor such as benzotriazole or other suitable corrosion inhibitors, for example, selected from the azole family and/or pyrole family. In various example embodiments, the corrosion inhibitor may have flame retardant properties, in which case, the coating need not include any other flame retardants besides the corrosion inhibitor.

A wide range of materials can be used for the resilient core member 22. For example, the resilient core member 22 may be made of urethane foam having a polyester film scrim attached thereto. Or, the resilient core member 22 may be made of polyether and/or polyester urethane foam. In addition, the resilient core member (e.g., urethane (polyester) foam, etc.) may be free of and not include flame retardant additives. Here, the foam core may have a density of between about 3.5 pounds per cubic foot and about 4.2 pounds per cubic foot, and a compression set (per ASTM D3574 (test D)) ranging from about 5% to about 15%. Alternative materials may also be used for the resilient core member 22, such as other resiliently compressible materials that are suitable for compression within an opening. Other materials and types can also be used for the scrim including fabrics. Yet, alternatively, the resilient core member 22 may not have a scrim attached thereto.

The resilient core member 22 may be any suitable resilient core member including, for example, a core member formed from a halogen-free polyurethane foam product available from The Woodbridge Group (Mississauga, Ontario, Canada) (e.g., product SC60CH, etc.), etc.

As an example, the resilient core member 22 may be formed from halogen-free polyurethane foam product SC60CH (from The Woodbridge Group). In this example, the product SC60CH used to form the resilient core member 22 is not flame rated and has the following physical properties: a density of about 3.5 to about 4.2 pounds per cubic foot; a 25% Indentation Force Deflection (IFD) of about 60 to about 80 pounds per 50 square inches; a charcoal color; contains no flame retardant (the foam product contains no flame retardant additives in the end product, and no flame retardant additives are added prior or during the manufacture of the foam product) (e.g., the foam product contains no ammonium compounds, either added thereto prior or during manufacture or in the end product, etc.); a tear strength of at least about 0.8 pounds per inch; a tensile strength of at least about 12 pounds per square inch; and an elongation (at break) of about 100%. In addition in this example, the foam product is a polyester that is die clickable. Embodiments of the present disclosure, however, are not limited to this particular foam as other materials may be used to make resilient core members in other embodiments.

A wide range of materials can be used for the electrically conductive layer 26. Example materials include conductive fillers within a layer, a metal layer, a conductive non-metal layer, metallic foils (e.g., aluminum foil, etc.), metal coated plastic films, etc. For example, the electrically conductive layer 26 may comprise a metalized or plated fabric in which the metal is copper, nickel, silver, palladium aluminum, tin, alloys, and/or combinations thereof. One particular example includes nickel/copper coated NRS fabric having a conductivity of less than about 0.07 ohms square. Another example includes nickel/copper coated taffeta having a conductivity of less than about 0.07 ohms square. A further example includes nickel/copper coated knit mesh having a conductivity of less than about 0.20 ohms square. In other examples, the electrically conductive layer 26 may comprise a layer of material that is impregnated with a metal material to thereby render the layer sufficiently electrically conductive for EMI shielding applications. The particular material(s) used for the electrically conductive layer 26 may vary, for example, depending on the desired electrical properties (e.g., surface resistivity, electrical conductivity, etc.) and/or abrasion resistance, which, in turn, can depend, for example, on the particular application in which the EMI shield 20 will be used.

In the illustrated embodiment, the adhesive layer 24 is an environmentally safe adhesive suitable for providing good bond strength between the electrically conductive layer 26 and the resilient core member 22. The adhesive layer 24 can include a wide range of suitable adhesives. The adhesives are formed into the adhesive layer 24 and may be laminated in production of the EMI shield 20 (e.g., fusion laminated to the electrically conductive layer 26, etc.).

For example, the adhesive layer 24 may include a solvent based polyester adhesive that is loaded with an effective amount of flame retardant (e.g., halogen-free flame retardant particles, etc.) to enable the EMI shield to achieve a predetermined flame rating while at the same time having good bond strength and retaining properties suitable (e.g., shielding effectiveness, bulk resistivity, etc.) for EMI shielding applications. Here, the solvent based polyester adhesive may include solvent to keep the adhesive liquid for coating purposes prior to drying. After the adhesive dries into a relatively thin film layer or form, the solvent evaporates leaving behind the polyester adhesive with the flame retardant mixed therein. After this evaporation, the amount of solvent still in the adhesive is relatively small (e.g., less than about 0.1%, etc.). The adhesive layer 24 may include an adhesive having a thickness of about 0.0025 inches, or any one or more of the adhesives disclosed herein (e.g., having any one or more of the specific compositions disclosed herein, etc.) within the scope of the present disclosure.

The adhesive layer 24 may include any of a wide range of flame retardants, including environmentally friendly flame retardants that are halogen free (e.g., free of halogens such as bromines, chlorines, etc.). Halogen-free flame retardants used in connection with the EMI shield 20 and the adhesive layer 24 thereof may include, for example, phosphorous-based flame retardants, etc. Particular examples of commercially available halogen-free phosphorous-based flame retardants are sold by Apex Chemical Company (Spartanburg, S.C.). Other example flame retardants that can be used include mineral oxides (e.g., magnesium hydroxide, antimony oxide, etc.), metal hydrates (e.g., aluminum trihydrate, etc.) boron compounds (e.g., boric acid, borax, etc.), melamines, silicones, etc.

While the adhesive layer 24 can include at least an effective amount of halogen-free flame retardant to achieve a predetermined flame rating, the adhesive layer 24 can also include more than that effective amount. For example, the adhesive layer 24 may include less than a predetermined percentage by dry weight of halogen-free flame retardant, below which percentage the adhesive layer 24 provides at least a predetermined bond strength. As recognized by the inventor hereof, there is a delicate balance that should be maintained with the halogen-free flame retardant and the adhesive layer 24. If the adhesive layer 24 contains too much halogen-free flame retardant, the bond strength can be compromised. But if the adhesive layer 24 does not include enough halogen-free flame retardant, then the EMI shield 20 may not be able to meet the desired UL-94 flame rating (e.g., V-0, V-1, V-2, HB, HF-1, etc.). Accordingly, the adhesive layer 24 in the illustrated EMI shield 20 includes at least an effective amount of halogen-free flame retardant for providing the shield with a UL-94 flame rating of V-0, but less than a predetermined percentage below which the adhesive provides at least a sufficient bond strength for EMI shielding applications (e.g., at least 4 ounces per inch width as determined by standard testing, for example, such as a 90 degree peel at 12 inches per minute, etc.). The inventor hereof has also determined (through extensive and time consuming work including testing over 300 different samples) an acceptable balance between flame resistance (using halogen-free flame retardants) and adhesive bond strength. The numerical ranges disclosed herein define such balances for obtaining such an acceptable flame resistance/adhesion balance to provide EMI shields that have an adhesive with adequate bond strength and adequate flame resistance (using halogen-free flame retardants) to achieve a flame rating of V-0 under UL-94.

The adhesive layer 24 may include an amount of halogen-free flame retardant of at least about 30% (+/−about 5%) but not more than about 70% by dry weight. Or, the adhesive layer 24 may include an amount of halogen-free flame retardant of at least about 50% but not more than about 63% by dry weight. Or, the adhesive layer 24 may include an amount of halogen-free flame retardant of at least about 54.5% to about 67.3% by dry weight. Or, the adhesive layer 24 may include an amount of halogen-free flame retardant of about 63% by dry weight. Or, the adhesive layer 24 may include an amount of halogen-free flame retardant of about 55% by dry weight. Or, the adhesive layer 24 may include an amount of halogen-free flame retardant of about 50% by dry weight.

FIG. 1C illustrates an example embodiment of another EMI shield 120 embodying one or more aspects of the present disclosure. The EMI shield 120 of this embodiment is similar to the EMI shield 20 previously described and illustrated in connection with FIGS. 1A and 1B. For example, the EMI shield 120 includes a resilient core member 122, an electrically conductive layer 126 generally surrounding the resilient core member 122, and an adhesive layer 124 bonding the electrically conductive layer 126 to the resilient core member 122. The adhesive layer 124 may include an effective amount of flame retardant such that the EMI shield 120 has a UL-94 flame rating of V-0. In this embodiment, the EMI shield 120 has a generally different shape than the EMI shield 20 illustrated in FIGS. 1A and 1B.

### EXAMPLES

The following examples are merely illustrative, and are not limiting to the disclosure in any way.

### Example 1

In one example, an adhesive suitable for use with EMI shields was made with a three component mixture, comprising 998 HS (a solvent based polyurethane adhesive product (having about 53% solids) made by DSM NeoSol Inc. (East Providence, R.I.)), AP-422 (a flame retardant ammonium polyphosphate (APP) product (having about 100% solids) made by Clariant GmbH (Germany)), and toluene (a solvent used to disperse the AP-422 and lower viscosity of the mixture). The components were mixed together using a suitable laboratory mixer and then coated on silicone-treated release paper using a draw down bar (e.g., having a width dimension of about 10 inches and a length dimension of about 8 inches, etc.) to make an adhesive coating (having a target weight of between about 3 ounces per square yard and about 4 ounces per square yard). The adhesive coating was next dried at a temperature of about 100 degrees Celsius for about 20 minutes to evaporate the toluene. A heat press was then used (at a temperature of about 350 degrees Fahrenheit for a duration of about 5 seconds) to bond the adhesive to a fabric (nickel/copper coated nylon ripstop) to form sheets of bonded adhesive and fabric. The sheets of bonded adhesive and fabric were then applied to foam cores made from product SC60CH (from The Woodbridge Group) to make foam-over-fabric EMI shielding gaskets for testing (having a width dimension of about 12.5 millimeters, a thickness dimension of about 3 millimeters, and a length dimension of about 125 millimeters).

The mixture of this example included about 75 grams (or about 53% by wet weight) of 998HS, about 36 grams (or about 26% by wet weight) of AP-422, and about 30 grams (or about 21% by wet weight) of toluene. As such, the mixture had a dry weight percentage of 998HS of about 52.5%, a dry weight percentage of AP-422 of about 47.5%, a viscosity of about 8,280 centipoise, and a weight pick-up of about 4.20 opsy.

The adhesive resulting from this mixture exhibited a bond strength of about 8.5 ounces per inch width on polyester film scrim, about 40 ounces per inch width on polyester foam, and about 8 ounces per inch width on polyether foam. These bond strengths were determined using a 90 degree peel test at a rate of about 12 inches per minute. For example, sheets of bonded adhesive and fabric (previously described) were cut to three samples each having a width dimension of about 1 inch and a length dimension of about 7 inches. Each of the samples was next laminated to a test material (e.g., polyester film scrim, polyester foam, polyether foam, etc.) and then pulled apart from the test material at an angle of about 90° and at a speed of about 12 inches per minute (using a tensile tester) to provide an average bond strength for the adhesive on the test material.

And, the EMI shields formed using the adhesive of this example achieved a UL-94 flame rating of V-0 (see, Table 2).

TABLE 2

| Sample | t₁ (s) | t₂ (s) | t₃ (s) | Result |
|---|---|---|---|---|
| 1 | 2 | 3 | 0 | V-0 |
| 2 | 8 | 1 | 0 | V-0 |
| 3 | 5 | 2 | 0 | V-0 |
| 4 | 6 | 1 | 0 | V-0 |
| 5 | 2 | 3 | 0 | V-0 |

Total Afterflame = 33 seconds
UL-94 Flame Rating = V-0

Corrosion tests (as generally described in Example 1) where also performed on EMI shields formed using the adhesive of this example at a substantially constant temperature of about 40 degrees Celsius and a substantially constant relative humidity of about 90%. The tests were performed on EMI shields using different electrically conductive layers comprising aluminum, galvanized steel, and brass. For each of the tests, surface resistivity was measured once a week (every 7 days) for 6 weeks for each EMI shield, and each EMI shield was visually (via the naked eye) inspected for visual signs of corrosion (e.g., spotting, etc.) and then rated on a corrosion scale from 0 to 5 (with a rating of 0 indicating no visible corrosion). Any rating higher than 1.0 was considered as a failed test. Table 3 illustrates the results of the corrosion tests for the EMI shields of this example (at a temperature of about 40 degrees Celsius and a relative humidity of about 90%). Surface resistivity readings (ohms per square) are provided for each weekly measurement from a T1 time of 0 weeks to a T7 time of 6 weeks, and corrosion ratings are provided in parentheticals thereafter. In Table 3, no readings were taken at T4.

TABLE 3

| Test | T1 | T2 | T3 | T4 | T5 | T6 | T7 | Result |
|---|---|---|---|---|---|---|---|---|
| Galvanized | 0.0291 | 0.0306 | 0.0321 | | 0.0651 | 0.0340 | 0.0343 | PASS |
| Steel | | (0) | (0) | | (0) | (0) | (0) | |
| Galvanized | 0.0301 | 0.0303 | 0.0323 | | 0.0545 | 0.0340 | 0.0369 | PASS |
| Steel | | (0) | (0) | | (0) | (0) | (0) | |
| Brass | 0.0281 | 0.0286 | 0.0291 | | 0.0502 | 0.0302 | 0.0340 | PASS |
| | | (0) | (0) | | (0) | (0) | (0) | |
| Aluminum | 0.0216 | 0.0217 | 0.0249 | | 0.0345 | 0.0242 | 0.0242 | PASS |
| | | (0) | (0) | | (0) | (0) | (0) | |
| Aluminum | 0.0249 | 0.0248 | 0.0248 | | 0.0382 | 0.0271 | 0.0270 | PASS |
| | | (0) | (0) | | (0) | (0) | (0) | |

### Example 2

In another example, an adhesive suitable for use with an EMI shield was made with a three component mixture, comprising 138-293C (a urethane adhesive product (having about 38% solids) made by DSM NeoSol Inc.), AP-462 (a flame retardant ammonium polyphosphate (APP) product (having about 100% solids) made by Clariant GmbH made from AP-422 (see, Example 1) by micro-encapsulation with melamine resin), and toluene (a solvent used to disperse the AP-462 and lower viscosity of the mixture). The components were mixed together as described in Example 1.

The mixture of this example included about 89 grams (or about 52% by wet weight) of 138-293C, about 50 grams (or about 29% by wet weight) of AP-462, and about 33 grams (or about 19% by wet weight) of toluene. As such, the mixture had a dry weight percentage of 138-293C of about 40.3%, a dry weight percentage of AP-462 of about 59.6%, a viscosity of about 2,580 centipoise, and a weight pick-up of about 3.62 opsy. The adhesive resulting from this mixture also had a thickness of about 0.09 millimeters and a melting point of about 140 degrees Celsius. In addition, the adhesive exhibited bond strengths (based on a 90 degree peel test at a rate of about 12 inches per minute as described in Example 1) of about 5 ounces per inch width on polyester scrim, about 15 ounces per inch width on polyether foam, about 40 ounces per inch width on polyester foam, and about 11 ounces per inch width on fabric. And, the EMI shield including this adhesive achieved a UL-94 flame rating of V-1 (see, Table 4).

TABLE 4

| Sample | t₁ (s) | t₂ (s) | t₃ (s) | Result |
|---|---|---|---|---|
| 1 | 6 | 0 | 0 | V-0 |
| 2 | 8 | 1 | 0 | V-0 |
| 3 | 8 | 0 | 0 | V-0 |
| 4 | 22 | 0 | 0 | V-1 |
| 5 | 13 | 0 | 0 | V-1 |

Total Afterflame = 58 seconds
UL-94 Flame Rating = V-1

Corrosion tests (as generally described in Example 1) where also performed on EMI shields formed using the adhesive of this example at a temperature of about 40 degrees Celsius and a relative humidity of about 90%. The tests were performed on EMI shields using electrically conductive layers formed from either galvanized steel or aluminum. For each of the tests, surface resistivity was measured about once a week (every 7 days) for 5 weeks for each EMI shield, and each EMI shield was visually inspected and then rated on a corrosion scale from 0 to 5 (with a rating of 0 indicating no visible corrosion). Any rating higher than 1.0 was considered as a failed test. Table 5 illustrates the results of the corrosion tests for the EMI shields of this example (at a temperature of about 40 degrees Celsius and a relative humidity of about 90%). Surface resistivity readings (ohms per square) are provided for each weekly measurement from a T1 time of 0 weeks to a T6 time of 5 weeks, and corrosion ratings are provided in parentheticals thereafter. In Table 5, no readings were taken at T5.

TABLE 5

| Test | T1 | T2 | T3 | T4 | T5 | T6 | Result |
|---|---|---|---|---|---|---|---|
| Galvanized | 0.0347 | 0.0350 | 0.0337 | 0.0340 | | 0.0369 | PASS |
| Steel | | (0) | (0) | (0) | | (0) | |
| Galvanized | 0.0336 | 0.0329 | 0.0359 | 0.0363 | | 0.0344 | PASS |
| Steel | | (0) | (0) | (0) | | (0) | |
| Aluminum | 0.0351 | 0.0355 | 0.0354 | 0.0362 | | 0.0359 | PASS |
| | | (0) | (0) | (0) | | (0) | |
| Aluminum | 0.0331 | 0.0345 | 0.0359 | 0.0366 | | 0.0369 | PASS |
| | | (0) | (0) | (0) | | (0) | |

### Example 3

This example is similar to Example 2. In this example, an adhesive suitable for use with an EMI shield was made with a four component mixture, comprising 138-293C (a urethane adhesive product (having about 38% solids) made by DSM NeoSol Inc.), AP-462 (a flame retardant ammonium polyphosphate (APP) product (having about 100% solids) made by Clariant GmbH made from AP-422 (see Example 1) by micro-encapsulation with melamine resin), toluene (a solvent used to disperse the AP-462 and lower viscosity of the mixture), and PCMLE 828 (an epoxy resin product made by Polochema (Taipei, Taiwan) used to improve adhesion of 138-293C). The components were mixed together as described in Example 1.

The mixture of this example included about 89 grams (or about 50% by wet weight) of 138-293C, about 50 grams (or about 28% by wet weight) of AP-462, about 33 grams (or about 19% by wet weight) of toluene, and about 6 grams of PCMLE 828 (or about 3% by wet weight). As such, the mixture had a dry weight percentage of 138-293C of about 37.6%, a dry weight percentage of AP-462 of about 55.7%, a dry weight percentage of PCMLE 828 of about 6.7%, a viscosity of about 2,520 centipoise, and a weight pick-up of about 3.7 opsy. The adhesive resulting from this mixture exhibited bond strengths (based on a 90 degree peel test at a rate of about 12 inches per minute as described in Example 1) of about 4 ounces per inch width on polyester scrim, about 40 ounces per inch width on polyether foam, about 40 ounces per inch width on polyester foam, and about 34 ounces per inch width on fabric. And the EMI shield including this adhesive achieved a UL-94 flame rating of V-0 (see, Table 6).

TABLE 6

| Sample | t₁ (s) | t₂ (s) | t₃ (s) | Result |
|---|---|---|---|---|
| 1 | 2 | 1 | 0 | V-0 |
| 2 | 9 | 1 | 0 | V-0 |
| 3 | 2 | 3 | 0 | V-0 |
| 4 | 3 | 1 | 0 | V-0 |
| 5 | 10 | 1 | 0 | V-0 |

Total Afterflame = 33 seconds
UL-94 Flame Rating = V-0

As previously noted, the adhesive of this example is similar to the adhesive described in Example 2. However, the adhesive of this example shows much improved burn test results (with decreased flame retardant). This is likely due (at least in part) to improved bond strengths (e.g., increased from 11 ounces per inch width on fabric in Example 2 to 34 ounces per inch width on fabric in this example, etc.), which may have helped prevent the EMI shields from opening during the flame test leading to the better burn test results.

### Example 4

This example is similar to Example 2. In this example, an adhesive suitable for use with an EMI shield was made with a three component mixture, comprising 138-293C (a urethane adhesive product (having about 38% solids) made by DSM NeoSol Inc.), AP-462 (a flame retardant ammonium polyphosphate (APP) product (having about 100% solids) made by Clariant GmbH made from AP-422 (see Example 1) by micro-encapsulation with melamine resin), and toluene (a solvent used to disperse the AP-462 and lower viscosity of the mixture). The components were mixed together as described in Example 1.

The mixture of this example included about 85 grams (or about 49% by wet weight) of 138-293C, about 55 grams (or about 32% by wet weight) of AP-462, and about 33 grams (or about 19% by wet weight) of toluene. As such, the mixture had a dry weight percentage of 138-293C of about 37%, a dry weight percentage of AP-462 of about 63%, and a viscosity of about 2,070 centipoise. The adhesive resulting from this mixture exhibited bond strengths (based on a 90 degree peel test at a rate of about 12 inches per minute as described in Example 1) of about 4 ounces per inch width on polyester scrim, about 11.5 ounces per inch width on polyether foam, about 40 ounces per inch width on polyester foam, and about 8 ounces per inch width on NRS fabric. And, the EMI shield including this adhesive achieved a UL-94 flame rating of V-0 (see, Table 7).

TABLE 7

| Sample | t₁ (s) | t₂ (s) | t₃ (s) | Result |
|---|---|---|---|---|
| 1 | 5 | 0 | 0 | V-0 |
| 2 | 9 | 0 | 0 | V-0 |
| 3 | 4 | 0 | 0 | V-0 |
| 4 | 10 | 0 | 0 | V-0 |
| 5 | 9 | 0 | 0 | V-0 |

Total Afterflame = 37 seconds
UL-94 Flame Rating = V-0

Corrosion tests (as generally described in Example 1) where also performed on EMI shields including the adhesive of this example at a temperature of about 50 degrees Celsius and a relative humidity of about 95%. The tests were performed on EMI shields using electrically conductive layers comprising aluminum. For each of the tests, surface resistivity (SR) was measured once a week (every 7 days) for 5 weeks, and each EMI shield tested was then rated on a corrosion scale from 0 to 5 (with a rating of 0 indicating no visible corrosion). Any rating higher than 1.0 was considered as a failed test. Table 8 illustrates the results of the corrosion tests for the EMI shields (at a temperature of about 50 degrees Celsius and a relative humidity of about 95%). Surface resistivity readings (ohms per square) are provided for each weekly measurement from a T1 time of 0 weeks to a T6 time of 5 weeks, and corrosion ratings are provided in parentheticals thereafter.

TABLE 8

| Test | T1 | T2 | T3 | T4 | T5 | T6 | Result |
|---|---|---|---|---|---|---|---|
| Aluminum | 0.0312 | 0.0328 | 0.0398 | 0.0357 | 0.0402 | 0.0436 | PASS |
| | | (0.5) | (0.5) | (0.5) | (0.5) | (0.5) | |
| Aluminum | 0.0333 | 0.0358 | 0.0375 | 0.0381 | 0.0381 | 0.0385 | PASS |
| | | (0.5) | (0.5) | (0.5) | (0.5) | (0.5) | |

### Example 5

In another example, an adhesive suitable for use with an EMI shield was made with a four component mixture, comprising 144-122 (a solvent based urethane adhesive product (with a solids content of about 28%) made by DSM NeoSol Inc.), OP-935 (a fine-grained organic phosphinate flame retardant product (having about 100% solids) made by Clariant GmbH), FR CROS 489 (a special grade ammonium polyphosphate (APP) product (having about 100% solids) coated with melamine and made by Budenheim Iberica (Germany)), PCMLE 828 (an epoxy resin product made by Polochema (Taipei, Taiwan), ED 5121 (a colorant product made by Cardinal Color, Inc. (Paterson, N.J.)), and toluene (a solvent used to disperse the FR CROS 489 and lower viscosity of the mixture). The components were mixed together as described in Example 1.

The mixture of this example included about 88 grams (or about 52% by wet weight) of 144-122, about 28 grams (or about 16.7% by wet weight) of OP-935, about 3.5 grams (or about 2.1% by wet weight) of FR CROS 489, about 13 g (or about 7.7% by wet weight) of PCMLE 828, about 0.3 grams of ED 5121 (or about 0.5% by wet weight), and about 35 grams (or about 21% by wet weight) of toluene. As such, the mixture had a dry weight percentage of 144-122 of about 35.6%, a combined dry weight percentage of OP-935 and FR CROS 489 of about 45.6%, and a dry weight percentage of PCMLE 828 of about 18.8%. In addition, the mixture had a viscosity of about 1,500 centipoise and a weight pick-up of about 2.28 opsy. And, the adhesive resulting from this mixture exhibited a bond strength (based on a 90 degree peel test at a rate of about 12 inches per minute as described in Example 1) of about 28 ounces per inch width on NRS, about 6 ounces per inch width on polyester scrim, about 40 ounces per inch width on polyester foam, about 6 ounces per inch width on polyether foam, and about 37 ounces per inch width on polyether scrim.

Further, EMI shields formed using the adhesive of this example achieved a UL-94 flame rating of V-0. Table 9 illustrates UL-94 test results for EMI shields formed using the adhesive to bond metalized fabric to a polyether foam core. Table 10 illustrates UL-94 test results for EMI shields formed using the adhesive to bond metalized fabric to a polyester foam core. And, Table 11 illustrates UL-94 test results for EMI shields formed using the adhesive to bond a foil/film laminate (comprising about 0.00035 inches of aluminum foil and about 0.00048 inches of polyester and having a surface resistivity of about 0.0032 ohms per square) to a foam core.

TABLE 9

| Sample | t₁ (s) | t₂ (s) | t₃ (s) | Result |
|---|---|---|---|---|
| 1 | 8 | 1 | 0 | V-0 |
| 2 | 8 | 0 | 0 | V-0 |
| 3 | 8 | 0 | 0 | V-0 |
| 4 | 7 | 0 | 0 | V-0 |
| 5 | 8 | 1 | 0 | V-0 |

Total Afterflame = 41 seconds
UL-94 Flame Rating = V-0

TABLE 10

| Sample | t₁ (s) | t₂ (s) | t₃ (s) | Result |
|---|---|---|---|---|
| 1 | 6 | 1 | 0 | V-0 |
| 2 | 7 | 0 | 0 | V-0 |
| 3 | 6 | 0 | 0 | V-0 |
| 4 | 6 | 1 | 0 | V-0 |
| 5 | 8 | 0 | 0 | V-0 |

Total Afterflame = 35 seconds
UL-94 Flame Rating = V-0

TABLE 11

| Sample | t₁ (s) | t₂ (s) | t₃ (s) | Result |
|---|---|---|---|---|
| 1 | 9 | 2 | 0 | V-0 |
| 2 | 5 | 3 | 0 | V-0 |
| 3 | 7 | 3 | 0 | V-0 |
| 4 | 8 | 1 | 0 | V-0 |
| 5 | 7 | 2 | 0 | V-0 |

Total Afterflame = 47 seconds
UL-94 Flame Rating = V-0

Corrosion tests (as generally described in Example 1) where also performed on EMI shields formed using the adhesive of this example. The tests were at a temperature of about 40 degrees Celsius and a relative humidity of about 90%. Two tests were performed on an EMI shield using each of aluminum, galvanized steel, and brass. For each of the tests, surface resistivity (SR) was measured once a week (every 7 days) for 6 weeks, and each EMI shield tested was then rated on a corrosion scale from 0 to 5 (with a rating of 0 being best). Any rating higher than 1.0 was considered as a failed test. Table 12 illustrates the results of the corrosion tests for this example for the first set of tests (at a temperature of about 40 degrees Celsius and a relative humidity of about 90%). Surface resistivity readings (ohms per square) are provided for each weekly measurement from a T1 time of 0 weeks to a T7 time of 6 weeks, and corrosion ratings are provided in parentheticals thereafter.

TABLE 12

| Test | T1 | T2 | T3 | T4 | T5 | T6 | T7 | Result |
|---|---|---|---|---|---|---|---|---|
| Aluminum | 0.0304 | 0.0311 | 0.0311 | 0.0317 | 0.0321 | 0.0318 | 0.0304 | PASS |
| | | (0) | (0) | (0) | (0) | (0) | (0) | |
| Aluminum | 0.0291 | 0.0309 | 0.0309 | 0.0311 | 0.0301 | 0.0303 | 0.0322 | PASS |
| | | (0) | (0) | (0) | (0) | (0) | (0) | |
| Galvanized | 0.0315 | 0.0288 | 0.0288 | 0.0297 | 0.0301 | 0.0320 | 0.0314 | PASS |
| Steel | | (0) | (0) | (0) | (0) | (0) | (0) | |
| Galvanized | 0.0321 | 0.0308 | 0.0308 | 0.0310 | 0.0318 | 0.0299 | 0.0304 | PASS |
| Steel | | (0) | (0) | (0) | (0) | (0) | (0) | |
| Brass | 0.0323 | 0.0298 | 0.0298 | 0.0329 | 0.0332 | 0.0331 | 0.0336 | PASS |
| | | (0) | (0) | (0) | (0) | (0.3) | (0.3) | |
| Brass | 0.0302 | 0.0298 | 0.0298 | 0.0304 | 0.0311 | 0.0309 | 0.0309 | PASS |
| | | (0) | (0) | (0) | (0) | (0.3) | (0.3) | |

### Example 6

In another example, an adhesive suitable for use with an EMI shield was made with a four component mixture, comprising Dispercoll 8758 (a water based polyurethane adhesive product (having a solids content of about 40%) made by Bayer MaterialScience (Pittsburgh, Pa.)), AP-422 (a flame retardant ammonium polyphosphate (APP) product (having about 100% solids) made by Clariant GmbH), Rheolate-2000 (a rheology modifier made by Elementis Specialties Inc. (Highstown, N.J.)), and water (a solvent used to disperse the AP-422 and lower the viscosity of the mixture). The components were mixed together as described in Example 1.

The mixture of this example included about 208 grams (or about 54% by wet weight) of Dispercoll 8758, about 96 grams (or about 25% by wet weight) of AP-422, about 4 grams (or about 1% by wet weight) of Rheolate-2000, and about 80 grams (or about 20% by wet weight) of water. As such, the mixture had a dry weight percentage of Dispercoll 8758 of about 46.1%, a dry weight percentage of AP-422 of about 53.3%, and a dry weight percentage of Rheolate-2000 of about 0.6%. In addition, the mixture had a viscosity of about 13,740 centipoise and a weight pick-up of about 3.4 opsy. And, the adhesive resulting from this mixture exhibited a bond strength (based on a 90 degree peel test at a rate of about 12 inches per minute as described in Example 1) of about 33 ounces per inch width on fabric, about 10 ounces per inch width on polyester scrim, about 40 ounces per inch width on polyether scrim, about 40 ounces per inch width on polyester foam, and about 40 ounces per inch width on polyether foam. And, the EMI shields including this adhesive achieved a UL-94 flame rating of V-1 (see, Table 13).

TABLE 13

| Sample | t₁ (s) | t₂ (s) | t₃ (s) | Result |
|---|---|---|---|---|
| 1 | 10 | 4 | 0 | V-0 |
| 2 | 10 | 0 | 0 | V-0 |
| 3 | 4 | 0 | 0 | V-0 |
| 4 | 5 | 1 | 0 | V-0 |
| 5 | 3 | 13 | 0 | V-1 |

Total Afterflame = 50 seconds
UL-94 Flame Rating = V-1

### Example 7

In this example, test specimens of EMI shields included a commercially available Woodbridge 4 pound per cubic foot density urethane foam product SC60CH from The Woodbridge Group. The Woodbridge urethane foam was about 0.125 inches (about 3.0 millimeters) thick by about 0.5 inches (about 12.5 millimeters) wide. The Woodbridge urethane foam was halogen-free and did not contain either halogenated flame retardant additives or non-halogenated flame retardant additives. As mentioned above, this particular Woodbridge foam product SC60CH had the following physical properties: a density of about 3.5 to about 4.2 pounds per cubic foot; a 25% Identification Force Deflection (IFD) of about 60 to about 80 pounds per 50 square inches; a charcoal color; contains no flame retardant (the foam product contains no flame retardant additives in the end product, and no flame retardant additives are added during the manufacture of the foam product); a tear strength of at least about 0.8 pounds per inch; a tensile strength of at least about 12 pounds per square inch; and an elongation of at least about 100%. In addition in this example, the foam product is a polyester that is die clickable. Embodiments of the present disclosure, however, are not limited to this particular foam as other materials may be used in other embodiments.

Continuing with this example, the SC60CH foam was made in a layer thickness of about 0.125 inches (about 3.0 millimeters), which was suitable for a UL sample. The test specimens further included an electrically conductive metalized fabric material laminated to an adhesive layer. The adhesive layer included a polyester adhesive with about 55% by dry weight of a halogen-free phosphorous-based flame retardant. The adhesive layer had a thickness of about 0.0025 inches.

In this series of tests, the fabric was provided with urethane that did not include flame retardant (Non-FR urethane). The Non-FR urethane coating included about 18% urethane solids such that the weight pick-up from the Non-FR urethane coating was about 0.15 opsy. Further, the fabric was laminated using a flat bed laminator set at 260 degrees Fahrenheit at approximately 15 feet per minute (although other suitable means can also be employed). The fabric and adhesive layer may also be trimmed to any suitable size or shape. The fabric was not provided with any halogen-free flame retardant.

The foam was joined together with the fabric and adhesive layer using a series of heated dies to form the shield in the desired shape. Samples of the EMI shields having dimensions of approximately 3.0 millimeters thick by 12.5 millimeters wide by 125 millimeters long were then tested for flame ratings per UL-94. The example flammability test results are set forth in Table 14 for purposes of illustration only.

TABLE 14

| Sample | t₁ (s) | t₂ (s) | t₃ (s) | Result |
|---|---|---|---|---|
| 1 | 6 | 0 | 0 | V-0 |
| 2 | 5 | 0 | 0 | V-0 |
| 3 | 7 | 0 | 0 | V-0 |
| 4 | 8 | 0 | 0 | V-0 |
| 5 | 5 | 1 | 0 | V-0 |

Total Afterflame = 32 seconds
UL-94 Flame Rating = V-0

As indicated in Table 14, the EMI shields of this example included at least an effective amount of halogen-free flame retardant within the adhesive to provide the shield with a UL-94 flame rating of V-0.

FIG. 12 illustrates the bonding strength of this particular adhesive (having about 55% by dry weight of a halogen-free phosphorous-based flame retardant) between the metalized fabric and a 0.001 inch thick polyester film scrim. The average bonding strength of this particular adhesive between the metalized fabric and scrim was about 35 ounces per inch width. The desired bonding strength, however, can vary depending, for example, on the particular application in which the EMI shield will be used.

### Example 8

In this example, test specimens of EMI shields also included the commercially available Woodbridge 4 pound per cubic foot density urethane foam product SC60CH (as described above). The Woodbridge urethane foam was about 0.125 inches (about 3.0 millimeters) thick by about U.S inches (about 12.5 millimeters) wide and was made in a layer thickness of about 0.125 inches (about 3.0 millimeters), which was suitable for a UL sample. The test specimens further included an electrically conductive metalized fabric material laminated to an adhesive layer. The adhesive layer included a polyester adhesive with about 63% by dry weight of a halogen-free phosphorous-based flame retardant.

In this series of tests, the fabric was not provided with a flame retardant. Further, the fabric was laminated using a flat bed laminator set at 260 degrees Fahrenheit at approximately 15 feet per minute (although other suitable means can also be employed). The fabric and adhesive layer may also be trimmed to any suitable size or shape.

The foam was joined together with the fabric and adhesive layer using a series of heated dies to form the shield in the desired shape. Samples of the EMI shields having dimensions of approximately 3.0 millimeters thick by 12.5 millimeters wide by 125 millimeters long were then tested for flame ratings per UL-94. The example flammability test results are set forth in Table 15 for purposes of illustration only.

TABLE 15

| Sample | t₁ (s) | t₂ (s) | t₃ (s) | Result |
|---|---|---|---|---|
| 1 | 9 | 0 | 0 | V-0 |
| 2 | 4 | 2 | 3 | V-0 |
| 3 | 14 | 0 | 3 | V-1 |
| 4 | 6 | 1 | 3 | V-0 |
| 5 | 9 | 1 | 3 | V-0 |

Total Afterflame = 46 seconds
UL-94 Flame Rating = V-1

As indicated in Table 15, the EMI shields of this example included at least an effective amount of halogen-free flame retardant within the adhesive to provide the shield with a UL-94 flame rating of V-1. These flammability results may be suitable for some applications as the desired flame rating can vary depending, for example, on the particular application in which the EMI shield will be used.

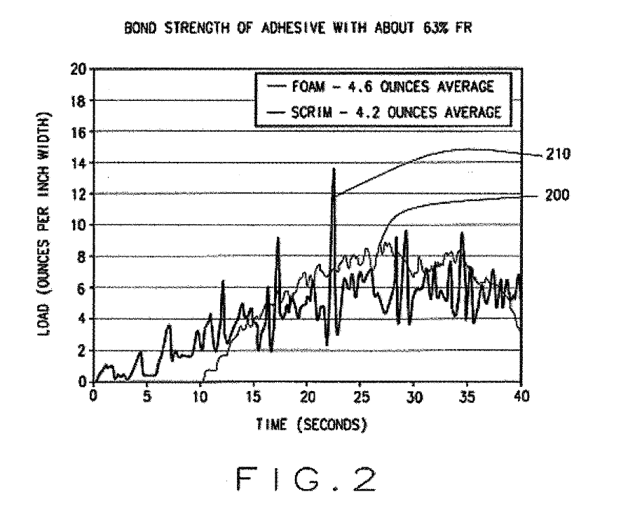

FIG. 2 illustrates the bonding strength of this particular adhesive (having about 63% by dry weight of a halogen-free phosphorous-based flame retardant) to the foam (represented by line 200) and to a polyester film scrim (represented by line 210) attached to the foam. As shown in FIG. 2, the average bonding strength between this particular adhesive and foam was about 4.6 ounces per inch width, and the average bonding strength between this particular adhesive and scrim was about 4.2 ounces per inch width. The desired bonding strength, however, can vary depending, for example, on the particular application in which the EMI shield will be used.

### Example 9

In this example, test specimens of EMI shields also included the commercially available Woodbridge 4 pound per cubic foot density urethane foam product SC60CH (as described above). The Woodbridge urethane foam was about 0.125 inches (about 3.0 millimeters) thick by about 0.5 inches (about 12.5 millimeters) wide and was made in a layer thickness of about 0.125 inches (about 3.0 millimeters), which was suitable for a UL sample. The test specimens further included an electrically conductive metalized fabric material that was again laminated to an adhesive layer. The adhesive layer included about 63% by dry weight of a halogen-free phosphorous-based flame retardant.

Unlike the previous Examples 7 and 8, in this example the fabric was provided with a material (e.g., a coating, etc.) that included halogen-free flame retardant and urethane such that the weight pick-up therefrom (from the material including the halogen-free flame retardant and urethane) was about 0.27 opsy. The halogen-free flame retardant was a water-based urethane dispersion (having about 13% solids by weight) including about 15% by weight of cyclic phosphonate esters with the remaining balance being de-ionized water. This phosphorous-based flame retardant liquid was then applied to the fabric by dipping the fabric into the flame retardant. The excess flame retardant was removed from the fabric (e.g., by squeezing the fabric with a pair of rubber nip rollers at about 20 pounds per square inch, etc.) and then drying the fabric in an oven when the oven temperature is at about 320 degrees Fahrenheit for 25 minutes residence time in the oven. After drying, the flame retardant urethane coating included about 54% phosphorous-based flame retardant and about 46% urethane.

In this example, the fabric was laminated using a flat bed laminator set at about 260 Fahrenheit at approximately 15 feet per minute (although it may be laminated using other suitable means for achieving a desired adherence). The foam was joined together with the electrically conductive layer and the adhesive laminate using a series of heated dies to form the shield in the desired shape. Samples of the EMI shields having dimensions of approximately 3.0 millimeters thick by 12.5 millimeters wide by 125 millimeters long were then tested for flame ratings per UL-94. The samples of this example in which the fabric was provided with halogen-free flame retardant, in combination with an adhesive loaded with about 63% by dry weight of halogen-free flame retardant, met the UL-94 flame ratings of V-0 as shown in Table 16.

TABLE 16

| Sample | t₁ (s) | t₂ (s) | t₃ (s) | Result |
|---|---|---|---|---|
| 1 | 6 | 0 | 1 | V-0 |
| 2 | 5 | 0 | 1 | V-0 |
| 3 | 6 | 1 | 1 | V-0 |
| 4 | 5 | 0 | 0 | V-0 |
| 5 | 5 | 0 | 1 | V-0 |

Total Afterflame = 28 seconds
UL-94 Flame Rating = V-0

### Example 10

In this example, test specimens of EMI shields also included the commercially available Woodbridge 4 pound per cubic foot density urethane foam product SC60CH (as described above). The Woodbridge urethane foam was about 0.125 inches (about 3.0 millimeters) thick by about 0.5 inches (about 12.5 millimeters) wide and was made in a layer thickness of about 0.125 inches (about 3.0 millimeters), which was suitable for a UL sample. The test specimens further included an electrically conductive metalized fabric material that was laminated to an adhesive layer. The adhesive layer included a polyester adhesive with about 50% by dry weight of a halogen-free phosphorous-based flame retardant.

The fabric was provided with a material (e.g., a coating, etc.) that included halogen-free flame retardant and urethane such that the weight pick-up therefrom was about 0.27 opsy. The halogen-free flame retardant was a water-based urethane dispersion (having about 13% solids by weight) including about 15% by weight of cyclic phosphonate esters with the remaining balance being de-ionized water. This phosphorous-based flame retardant liquid was applied to the metalized fabric layer by dipping the metalized fabric into the flame retardant. The excess flame retardant was removed from the metalized fabric (e.g., by squeezing the fabric with a pair of rubber nip rollers at twenty pounds per square inch, etc.) and then drying the metalized fabric in an oven when the oven temperature is at about 320 degrees Fahrenheit for 25 minutes residence time in the oven. After drying, the flame retardant urethane coating included about 54% phosphorous-based flame retardant and about 46% urethane.

In this example, the fabric was laminated using a flat bed laminator set at about 260 degrees Fahrenheit at approximately 15 feet per minute (although it may be laminated using other suitable means for achieving a desired adherence). The foam was joined together with the electrically conductive layer and the adhesive laminate using a series of heated dies to form the shield in the desired shape. Samples of the EMI shields having dimensions of approximately 3.0 millimeters thick by 12.5 millimeters wide by 125 millimeters long were then tested for flame ratings per UL-94. As shown in Table 17, the samples of this example in which the fabric was provided with halogen-free flame retardant, in combination with an adhesive loaded with about 50% by dry weight of halogen-free flame retardant, met the UL-94 flame ratings of V-0.

TABLE 17

| Sample | t₁ (s) | t₂ (s) | t₃ (s) | Result |
|---|---|---|---|---|
| 1 | 5 | 2 | 1 | V-0 |
| 2 | 5 | 0 | 1 | V-0 |
| 3 | 4 | 0 | 1 | V-0 |
| 4 | 5 | 1 | 1 | V-0 |
| 5 | 5 | 0 | 1 | V-0 |

Total Afterflame = 27 seconds
UL-94 Flame Rating = V-0

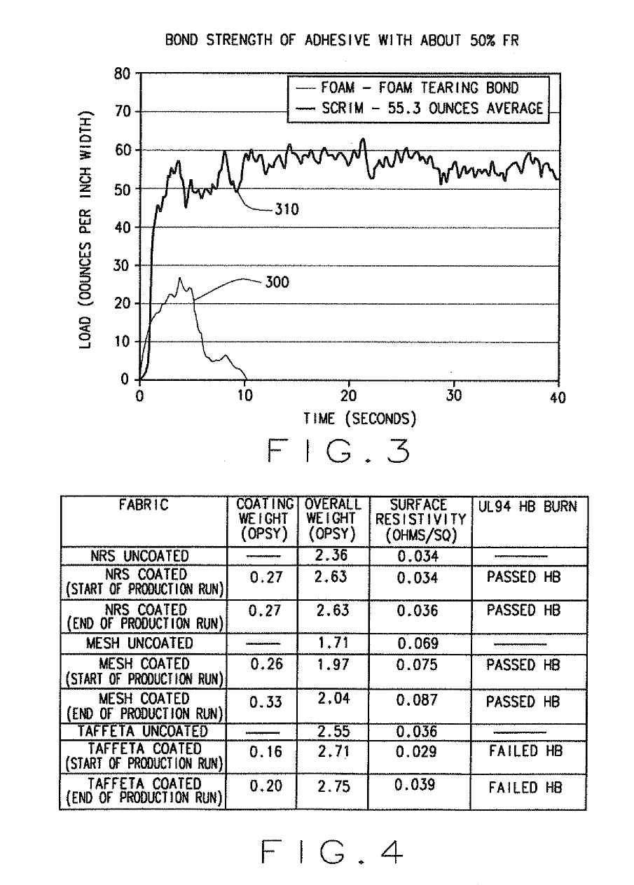

FIG. 3 illustrates the bonding strength of this particular adhesive (having about 50% by dry weight of halogen-free phosphorous-based flame retardant) to the foam (represented by line 300) and to a polyester film scrim (represented by line 310) attached to the foam. As shown in FIG. 3, the bonding strength between this particular adhesive and foam was sufficiently strong to tear the foam, and the average bonding strength between this particular adhesive and scrim was about 55.3 ounces per inch width. The desired bonding strength, however, can vary depending, for example, on the particular application in which the EMI shield will be used.

### Example 11

In this example, surface resistivity and flame ratings were evaluated for three example materials (NRS, mesh, and taffeta) suitable for use with example embodiments of EMI shields of the present disclosure. Any one of the fabrics included in this example can be bonded to a resilient core member (e.g., urethane foam, etc.) with an adhesive that includes halogen-free flame retardant to thereby form an EMI shield. FIG. 4 provides surface resistivity of these example fabrics when uncoated and when coated with halogen-free flame retardant urethane. As shown in FIG. 4, the coated and uncoated fabrics all have a surface resistivity of less than 0.10 ohms per square In addition, FIG. 4 also indicates that some of the coated fabrics achieve a UL rating of HB, such as the coated NRS. While the halogen-free flame retardant provided to the fabrics in FIG. 4 was not enough to significantly increase surface resistivity, it was a sufficient amount so as to allow the adhesive to be loaded with less halogen-free flame retardant in order to obtain a higher adhesive bond strength and also achieve a UL-94 flame rating of V-0 for EMI shields produced using the fabrics. Alternatively, other flame retardants, other amounts of flame retardants, and other materials besides the fabrics shown in FIG. 4 can be used for EMI shields within the scope of the present disclosure.

### Example 12

In this example, crush and fold characteristics of NRS was evaluated. FIG. 5 is a table of data collected during the crush and fold testing of a first NRS fabric coated with urethane that did not include flame retardant (Non-FR urethane), and a second NRS fabric coated with halogen-free flame retardant urethane (FR urethane). The first NRS fabric was provided with an amount of Non-FR urethane such that the weight pick-up therefrom was about 0.23 opsy, and the second NRS fabric was provided with an amount of FR urethane such that the weight pick-up therefrom was about 0.27 opsy. Generally, crush and fold tests measure abuse resistance of a plated metal fabric by folding and crumpling the fabric. In this particular example, the first NRS fabric coated with Non-FR urethane and the second NRS fabric coated with halogen-free flame retardant urethane were both tested for shielding effectiveness between 5 megahertz and 1,000 megahertz and for surface resistivity. The fabrics were then folded in quarters, rolled into cylinders, and crushed in a 10 milliliter syringe using a 5 pound weight. The testing was repeated until the average shielding effectiveness dropped below 60 decibels across the frequency range.

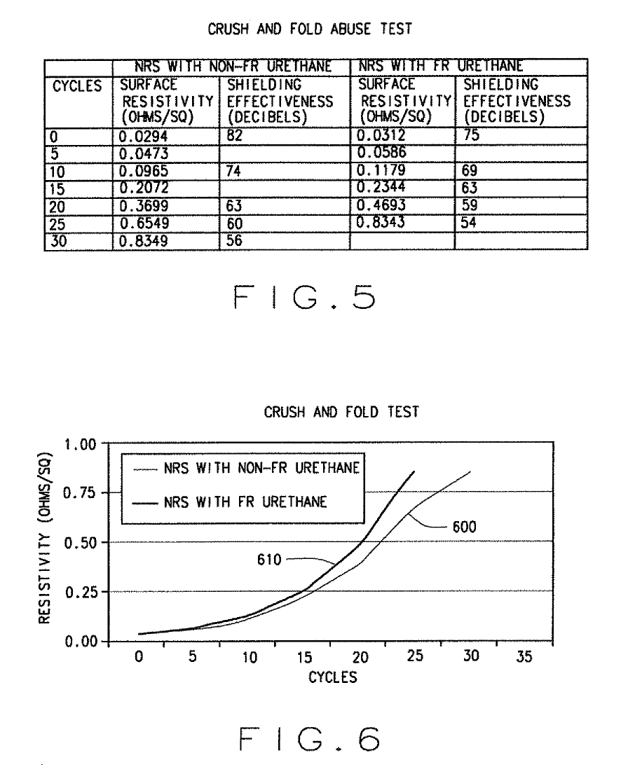

FIG. 6 is an example line graph created from the surface resistivity data shown in FIG. 5 of this example. In FIG. 6, line 600 represents surface resistivity for the first NRS fabric coated with Non-FR urethane, and line 610 represents surface resistivity for the second NRS fabric coated with halogen-free flame retardant urethane.

### Example 13

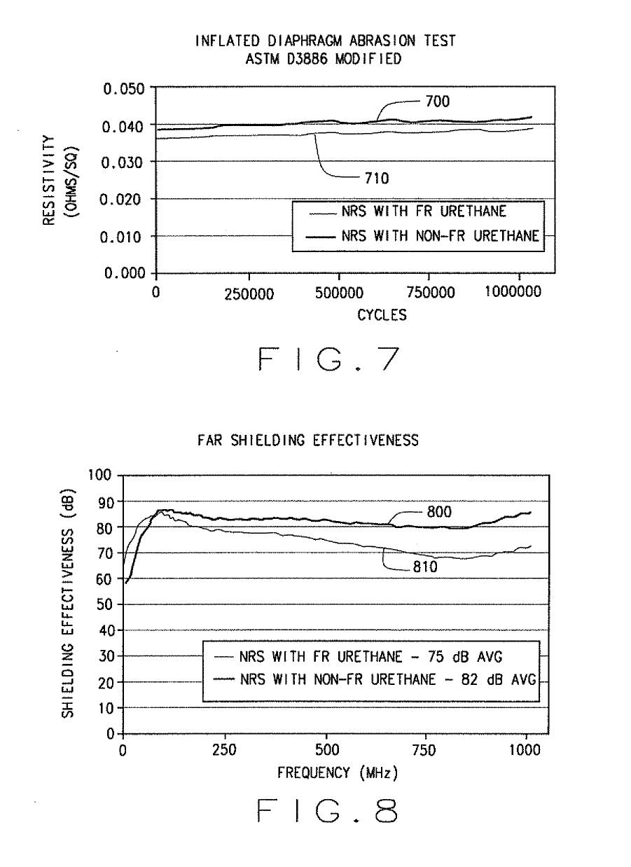

In this example, inflated diaphragm abrasion testing of NRS was evaluated. FIG. 7 is an example line graph showing surface resistivity versus number of cycles during the inflated diaphragm abrasion testing of a first NRS fabric coated with an amount of Non-FR urethane such that the weight pick-up therefrom was about 0.23 opsy, and a second NRS fabric coated with an amount of halogen-free flame retardant urethane such that the weight pick-up therefrom was about 0.27 opsy. In FIG. 7, line 700 represents surface resistivity for the first NRS fabric coated with Non-FR urethane, and line 710 represents surface resistivity for the second NRS fabric coated with halogen-free flame retardant urethane.

### Example 14

In this example, shielding effectiveness of NRS was evaluated. FIG. 8 is an example line graph illustrating the shielding effectiveness (in decibels) versus electromagnetic interference frequency (in megahertz) for a first nickel copper NRS fabric coated with an amount of Non-FR urethane such that the weight pick-up therefrom was about 0.23 opsy, and second a nickel copper NRS fabric coated with halogen-free flame retardant urethane such that the weight pick-up therefrom was 0.27 opsy. In FIG. 8, line 800 represents shielding effectiveness for the first NRS fabric coated with Non-FR urethane, and line 810 represents shielding effectiveness for the second NRS fabric coated with halogen-free flame retardant urethane. As noted in FIG. 8, the first NRS fabric coated with Non-FR urethane had an average shielding effectiveness of about 82 decibels across the frequency range of 5 megahertz to 1,000 megahertz. The second NRS fabric coated with halogen-free flame retardant urethane had an average shielding effectiveness of about 75 decibels across the frequency range of 5 megahertz to 1,000 megahertz.

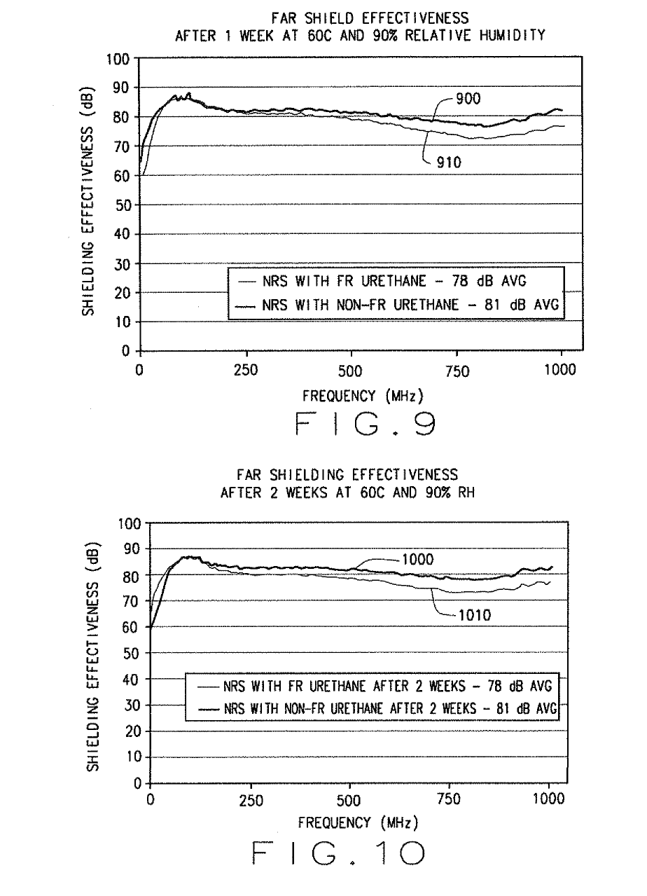

FIG. 9 is an example line graph illustrating the shielding effectiveness (in decibels) versus electromagnetic interference frequency (in megahertz) for the first and second nickel copper NRS fabrics shown in FIG. 8 after one week of environmental exposure within a relative humidity and temperature chamber at about 60 degrees Celsius and about 90% relative humidity. In FIG. 9, line 900 represents shielding effectiveness for the first NRS fabric coated with Non-FR urethane, and line 910 represents shielding effectiveness for the second NRS fabric coated with halogen-free flame retardant urethane. As noted in FIG. 9, the first NRS fabric coated with Non-FR urethane had an average shielding effectiveness of about 81 decibels across the frequency range of 5 megahertz to 1,000 megahertz. The second NRS fabric coated with halogen-free flame retardant urethane had an average shielding effectiveness of about 78 decibels across the frequency range of 5 megahertz to 1,000 megahertz.

FIG. 10 is an example line graph illustrating the shielding effectiveness (in decibels) versus electromagnetic interference frequency (in megahertz) for the first and second nickel copper NRS fabrics shown in FIG. 8, but after two weeks of environmental exposure within a humidity and temperature chamber at about 60 degrees Celsius and about 90% relative humidity. In FIG. 10, line 1000 represents shielding effectiveness for the first NRS fabric coated with Non-FR urethane, and line 1010 represents shielding effectiveness for the second NRS fabric coated with halogen-free flame retardant urethane. As noted in FIG. 10, the first NRS fabric coated with Non-FR urethane had an average shielding effectiveness of about 81 decibels across the frequency range of 5 megahertz to 1,000 megahertz. The second NRS fabric coated with halogen-free flame retardant urethane had an average shielding effectiveness of about 78 decibels across the frequency range of 5 megahertz to 1,000 megahertz.

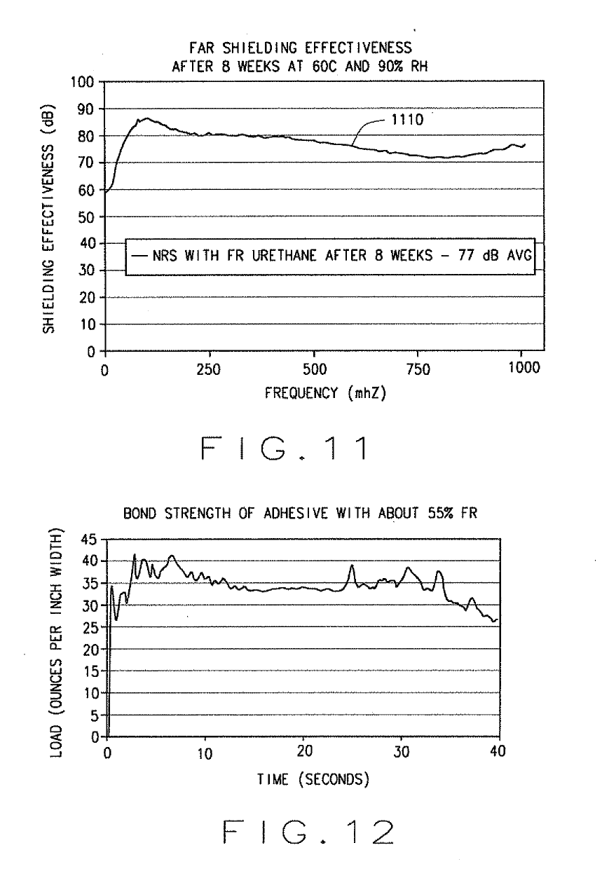

FIG. 11 is an example line graph illustrating shielding effectiveness versus electromagnetic interference frequency for the second nickel copper NRS fabrics coated with the halogen-free flame retardant urethane shown in FIG. 8, but after eight weeks of environmental exposure within a humidity and temperature chamber at 60 degrees Celsius and 90% relative humidity. In FIG. 11, line 1110 represents the shielding effectiveness for the NRS fabric coated with halogen-free flame retardant urethane. As noted in FIG. 11, the NRS fabric coated with halogen-free flame retardant urethane had an average shielding effectiveness of about 77 decibels across the frequency range of 5 megahertz to 1,000 megahertz.

In Examples 7 and 8, the fabric was not provided with any halogen-free flame retardant. But in Examples 9 and 10, the fabric was provided with halogen-free flame retardant urethane such that the weight pick-up therefrom was about 0.27 opsy. In other example embodiments, however, the electrically conductive fabric (e.g., metal coated (e.g., nickel/copper coated, etc.) NRS fabrics, mesh fabrics, taffeta fabrics, woven fabrics, non-woven fabrics, knitted fabrics, etc.) can be provided with (e.g., coated, impregnated, combinations thereof, etc.) a different amount of halogen-free flame retardant. For example, some example embodiments may include an electrically conductive fabric provided with halogen-free flame retardant urethane (e.g., a coating, etc.) such that the weight pick-up therefrom is between about 0.16 opsy and about 0.33 opsy (e.g., about 0.16 opsy, about 0.20 opsy, about 0.26 opsy, about 0.27 opsy, about 0.33 opsy, etc.).

The above examples provide a sampling of the at least 170 experiments performed by the inventor in attempt to achieve halogen-free EMI shields capable of achieving flame ratings of V-0 under UL-94 while maintaining structural integrity during fire (e.g., while maintaining adhesive bonds between resilient core members and electrically conductive layers, etc.). The examples also help illustrate the counterintuitive way recognized by the inventor to achieve the higher flame ratings of V-0. More specifically, the inventor recognized that reducing the amount of flame retardant in adhesive layers of the EMI shields (bonding the resilient core members to the electrically conductive layers) counterintuitively increased the flame retardation/rating for the overall EMI shields, because the increased bond strength provided by the adhesive layers (due to the lower flame retardant loading in the adhesive layers) prevented the EMI shields from opening up during fire. This approach is contrary to the logical path of increasing flame retardation/flame ratings by increasing the amount of flame retardant in the overall EMI shields (e.g., in the adhesive layers of the EMI shields, etc.). But the inventor recognized that bond strengths over a particular threshold (e.g., bond strengths of at least ten ounces per inch width, etc.) would achieve increased flame retardation as compared to EMI shields having more flame retardant in their adhesive layers.

Thus, through the inventor's numerous experiments, the inventor discovered that there is a careful and delicate balance between adhesive bond strength and amount flame retardant in the adhesive needed to achieve halogen-free EMI shields capable of achieving flame ratings of V-0. This delicate balance is shown, for example, by a comparison of Examples 7 and 8. In Example 7, the EMI shields included an adhesive layer having about 55% by dry weight of halogen-free flame retardant and a fabric having non-flame retardant urethane provided thereto. The EMI shields of Example 7 were able to achieve a flame rating of V-0 under UL-94. In Example 8, the EMI shields included an adhesive layer having more halogen-free flame retardant than in Example 7 (63% by dry weight) but were only able to achieve a flame rating of V-1 under UL-94. Neither Example 7 or Example 8 included any flame retardant additives in the foam or any flame retardant coating on the fabric. The bond strength of the adhesive layer (with 63% flame retardant) in Example 8 (about 4.6 ounces per inch width) was significantly less than the bond strength of the adhesive layer (with 55% flame retardant) in Example 7 (about 35 ounces per inch width). This weaker bond strength in Example 8 led to the V-1 burn test results (and the V-0 burn test failures), since the EMI shields of Example 8 opened up during the flame tests (as the heat from the fire of the flame tests caused the adhesive layers of the EMI shields to fail and allowing the fabric to separate from the foam such that the EMI shields open up). In short, the EMI shields of Example 8 had more flame retardant inside (63%), but still failed the burn tests because of the weaker bond strength associated with the particular adhesive layer used therein.

The above examples also illustrate the reliance of bond strength of adhesives in the EMI shields on composition of the adhesives (e.g., types, amounts, etc. of flame retardants added to the adhesives, etc.).

The disclosure and teachings herein may be applied in a wide range of applications. Accordingly, the specific references to electromagnetic interference shielding applications should not be construed as limiting the scope of embodiments of the present disclosure to use in only electromagnetic interference shielding applications.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the term “and/or” includes any and all combinations of one or more of the associated listed items. Also as used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms, “next,” etc., when used herein, do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The disclosure herein of particular values and particular ranges of values for given parameters are not exclusive of other values and ranges of values that may be useful in one or more of the examples disclosed herein. Moreover, it is envisioned that any two particular values for a specific parameter stated herein may define the endpoints of a range of values that may be suitable for the given parameter (i.e., the disclosure of a first value and a second value for a given parameter can be interpreted as disclosing that any value between the first and second values could also be employed for the given parameter). Similarly, it is envisioned that disclosure of two or more ranges of values for a parameter (whether such ranges are nested, overlapping or distinct) subsume all possible combination of ranges for the value that might be claimed using endpoints of the disclosed ranges.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. An electromagnetic interference (EMI) shield comprising:
a resilient core member comprising cellular polymeric foam;
an electrically conductive layer; and
an adhesive bonding the electrically conductive layer to the resilient core member;
wherein the electrically conductive layer has a surface resistivity of less than about 0.2 ohms per square after at least about 1,000 hours of exposure of the EMI shield to a temperature of at least about 40 degrees Celsius and a relative humidity of at least about 90%;
wherein the adhesive includes about 30% to about 63% by dry weight of halogen-free flame retardant;
wherein the adhesive has no more than a maximum of 900 parts per million chlorine, no more than a maximum of 900 parts per million bromine, and no more than a maximum of 1,500 parts per million total halogens; and
wherein the EMI shield has a flame rating of V-0 under Underwriter's Laboratories (UL) Standard No. 94.

2. The EMI shield of claim 1, wherein the adhesive includes:
about 25% to about 60% by dry weight of a resin;
about 30% to about 50% by dry weight of an organic phosphorus flame retardant; and
about 1% to about 10% by dry weight of a melamine derivative flame retardant.

3. The EMI shield of claim 1, wherein:
the resilient core member has no more than a maximum of 900 parts per million chlorine, no more than a maximum of 900 parts per million bromine, and no more than a maximum of 1,500 parts per million total halogens; and
the electrically conductive layer has no more than a maximum of 900 parts per million chlorine, no more than a maximum of 900 parts per million bromine, and no more than a maximum of 1,500 parts per million total halogens.

4. The EMI shield of claim 3, wherein the EMI shield has no more than a maximum of 900 parts per million chlorine, no more than a maximum of 900 parts per million bromine, and no more than a maximum of 1,500 parts per million total halogens.

5. The EMI shield of claim 4, wherein the resilient core member, the electrically conductive layer, and/or the adhesive are entirely free of halogen.

6. The EMI shield of claim 1, wherein the EMI shield is free of red phosphorus flame retardant and/or expandable carbon graphite.

7. The EMI shield of claim 1, wherein the EMI shield includes no more than a maximum of about 1,000 parts per million of antimony.

8. The EMI shield of claim 1, wherein the resilient core member is free of flame retardant.

9. The EMI shield of claim 8, wherein the resilient core member is entirely free of flame retardant.

10. The EMI shield of claim 1, wherein the resilient core member has a density of between about 3 pounds per cubic foot and about 5 pounds per cubic foot.

11. The EMI shield of claim 10, wherein the resilient core member has a density of between about 3.5 pounds per cubic foot and about 4.2 pounds per cubic foot and a compression set less than about 15%.

12. The EMI shield of claim 1, wherein the adhesive defines a layer having a thickness of less than about 0.5 millimeters.

13. The EMI shield of claim 1, wherein the EMI shield has a shielding effectiveness of greater than about 60 decibels and a range of operating temperatures of between about minus 40 degrees Celsius and about 70 degrees Celsius.

14. The EMI shield of claim 1, wherein the EMI shield consists of only three layers, including:
a first layer defined solely by the resilient core member;
a second layer defined solely by the adhesive that includes the halogen-free flame retardant; and
a third layer defined solely by the electrically conductive layer.

15. The EMI shield of claim 1, wherein the EMI shield consists of only the resilient core member, the adhesive that includes the halogen-free flame retardant, and the electrically conductive layer.

16. An electronic device including the EMI shield of claim 1.

17. A thermoplastic polyurethane adhesive suitable for use with an EMI shield, the thermoplastic polyurethane adhesive comprising:
about 30% to about 63% by dry weight of halogen-free flame retardant;
wherein the thermoplastic polyurethane adhesive is configured to produce a bond strength of at least about 4 ounces per inch width to a polyester film at a thickness of the thermoplastic polyurethane adhesive of about 0.5 millimeters or less;
wherein the thermoplastic polyurethane adhesive is configured to produce a bond strength of at least about 10 ounces per inch width to a foam material at a thickness of the thermoplastic polyurethane adhesive of about 0.5 millimeters or less;
wherein the thermoplastic polyurethane adhesive is configured to produce a bond strength of at least about 10 ounces per inch width to a fabric material at a thickness of the thermoplastic polyurethane adhesive of about 0.5 millimeters or less; and
wherein the thermoplastic polyurethane adhesive has no more than a maximum of 900 parts per million chlorine, no more than a maximum of 900 parts per million bromine, and no more than a maximum of 1,500 parts per million total halogens.

18. The thermoplastic polyurethane adhesive of claim 17, wherein the thermoplastic polyurethane adhesive comprises:
about 25% to about 60% by dry weight of urethane;
about 30% to about 50% by dry weight of organic phosphorus flame retardant; and
about 1% to about 10% by dry weight of melamine derivative flame retardant;

19. The thermoplastic polyurethane adhesive of claim 17, wherein the thermoplastic polyurethane adhesive is free of red phosphorus flame retardant and/or expandable carbon graphite and/or antimony.

20. A halogen-free fabric-over-foam electromagnetic interference (EMI) shielding gasket comprising:
a resilient core member comprising urethane foam;
an electrically conductive layer; and
a thermoplastic polyurethane adhesive bonding the electrically conductive layer to the resilient core member with a bond strength of at least 4 ounces per inch width;
wherein the resilient core member is free of flame retardant;
wherein the resilient core member has a density between 3.5 pounds per cubic foot and 4.2 pounds per cubic foot and a compression set between 5% and 15%;
wherein the electrically conductive layer has a surface resistivity of less than 0.07 ohms per square after at least 1,000 hours of exposure of the EMI shield to a temperature of at least 40 degrees Celsius and a relative humidity of at least 90%;
wherein the thermoplastic polyurethane adhesive defines a layer having a thickness of 0.5 millimeters or less;
wherein the resilient core member, the electrically conductive layer, and the thermoplastic polyurethane adhesive combined have no more than a maximum of 900 parts per million chlorine, no more than a maximum of 900 parts per million bromine, and no more than a maximum of 1,500 parts per million total halogens such that the gasket is halogen free; and
wherein the EMI shield has a flame rating of V-0 under Underwriter's Laboratories (UL) Standard No. 94.

21. The EMI shielding gasket of claim 20, wherein the resilient core member has a 25% indentation force deflection between 60 pounds per 50 square inches and 80 pounds per 50 square inches, a tear strength of at least 0.8 pounds per inch, and a tensile strength of at least 12 pounds per square inch.

22. The EMI shielding gasket of claim 20, wherein the thermoplastic polyurethane adhesive includes 30% to 63% by dry weight of halogen-free flame retardant.

23. The EMI shielding gasket of claim 20, wherein the thermoplastic polyurethane adhesive includes:
25% to 60% by dry weight of urethane;
30% to 50% by dry weight of organic phosphorus flame retardant; and
1% to 10% by dry weight of melamine derivative flame retardant.

24. The EMI shielding gasket of claim 23, wherein the organic phosphorus flame retardant includes an organic phosphinate flame retardant and the melamine derivative flame retardant includes an ammonium polyphosphate coated with melamine, and wherein the thermoplastic polyurethane adhesive further includes 10% to 30% by dry weight of an epoxy resin.
